(19) United States
(12) Patent Application Publication
(10) Pub. No.: US 2022/0129598 A1
(43) Pub. Date: Apr. 28, 2022

(54) SHAPE SYSTEMS AND METHODS

(71) Applicant: Georgia Tech Research Corporation, Atlanta, GA (US)

(72) Inventors: Tzu-Chieh K. Hong, Atlanta, GA (US); Athanassios N. Economou, Atlanta, GA (US)

(21) Appl. No.: 17/558,799

(22) Filed: Dec. 22, 2021

Related U.S. Application Data
(63) Continuation of application No. 17/221,746, filed on Apr. 2, 2021, now abandoned.
(60) Provisional application No. 62/004,608, filed on May 29, 2014.

(51) Int. Cl. G06F 30/13; G06F 30/23; G06F 30/12; G06T 11/20

(52) U.S. Cl. CPC G06F 30/13; G06T 11/203; G06F 30/12; G06F 30/23

(57) ABSTRACT

Systems and methods that fundamentally redefine the way shapes are represented, indexed, queried and operated upon. Visual rules (shape rules drawn in a 2D or 3D modeling system) dominate over symbolic rules (instructions defined in some programming language), providing a robust technology for professionals who use drawings and visual models to develop and communicate their ideas. The system structure includes a communication/control layer, a shape rule compiler, a design initializer, a maximal line modeler, shape embedding engine, and a rule application unit.

### CROSS-REFERENCE TO RELATED APPLICATIONS

This application is continuation of and claims benefit of priority pursuant to 35 USC § 120 of, U.S. application Ser. No. 17/221,746 filed 2 Apr. 2021, which application claims benefit under 35 USC § 119(e) of U.S. Provisional Patent Application No. 62/004,608 filed 3 Apr. 2020, the entirety of which is incorporated herein by reference as if set forth herein in its entirety.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### SEQUENCE LISTING

Not Applicable

### STATEMENT REGARDING PRIOR DISCLOSURES BY THE INVENTOR OR A JOINT INVENTOR

Not Applicable

### BACKGROUND OF THE DISCLOSURE

### 1. Field of the Invention

The present invention relates to shape systems and methods that disrupt the field of convention shape grammar interpreter, and more particular relates to a novel computational technology that deals comprehensively with the issues plaguing shape embedding and shape replacement in generative modelling in Computer-Aided Design/Modeling (CAD/CAM).

### 2. Description of Related Art

Imagine working on a paper with your familiar word-processor in your computer. As you work, you decide to edit a word only to realize that the word cannot be selected as intended, but only a part of it, few letters in no apparent order. You try to edit another occurrence of the same word in the text and you realize that this time your selection included some fragments of other words adjacent to the one you started with. Frustrated you erase the complete selected mess determined to retype the correct version of the text, only to realize that there are other letters and fragments of letters underneath the text you deleted. In the end you decide that the only way to modify the text is to retype everything.

Clearly, this scenario is imaginative, but it is used here as a prompt to illustrate the everyday frustration of designers, engineers, scientists, and all users working with lines in 2D and 3D geometric models. Every designer, engineer and scientist who works with geometry models knows how difficult is to work with existing files—especially if they are done by others—and how difficult or often impossible, simple operations with lines like the “Find” and “Replace” command discussed above, can be.

This odd situation has of course not been unnoticed. As early as the early seventies Stiny and Gips called out the need for a uniform representation of shape and over the years Stiny and a growing number of scholars, educators, designers and scientists relentlessly built a school of thought starting at the Open University and the Royal College of Art at UK, later at UCLA and CMU, and since the mid-nineties at MIT, put together the formidable theoretical formalism of shape grammars with the promise of revolutionizing computer-aided design (CAD) (see for example, [31], [34], [21], [20], [10]). Shape grammars' foregrounding of shape rules drawn in a 2D or 3D modeling system over instructions defined in some programming language have provided a robust theory for designers to believe in but nevertheless a formidable challenge to implement. In fact, up-to-date, there are more than 70 shape grammar interpreters that have been designed since the mid-seventies ([13], [7], [6], [11], [18]) all claiming they can address a particular aspect of shape mapping replacement, the paramount characteristic of this technology—and still none of them has solved conclusively the problem of “Find” and “Replace,” casting thus a shadow of doubt on whether this task is feasible. An updated view of these lists is given below in Table I featuring 22 general-purpose shape grammar interpreters.

TABLE I
List Of General-Purpose Shape Grammar Implementations

| No. | Name/Reference No. | Author | Year |
|---|---|---|---|
| 1 | Shape Grammar Interpreter/[22] | Krishnamurti | 1982 |
| 2 | Shape Grammar Interpreter/[23] | Krishnamurti & Giraud | 1986 |
| 3 | Shape Grammar System/[5] | Chase | 1989 |
| 4 | Genesis (CMU) | Heisserman | 1991 |
| 5 | GRAIL/[24] | Krishnamurti | 1992 |
| 6 | Genesis (Boeing) | Heisserman | 1994 |
| 7 | GEdit/[37] | Tapia | 1999 |
| 8 | Parametric Shape Grammar Interpreter | Cagan & McCormmack | 2002 |
| 9 | Shape Grammar Implementation U13/[7] | Chau | 2004 |
| 10 | Curve-based SGI | Cagan & McCormmack | 2006 |
| 11 | Sub-shape Detector | Jowers | 2008 |
| 12 | Parametric SG Interpreter | Yue & Krishnamurti | 2009 |
| 13 | SD2 | Jowers | 2010 |
| 14 | QI/[19] | Jowers | 2011 |
| 15 | SGI for Rectilinear Forms | Trescak, Esteva & Rodriguez | 2012 |
| 16 | Visual Interactive 3D Spatial Grammar | Hoisl & Shea | 2012 |
| 17 | DESIGNA/[9] | Correia | 2013 |
| 18 | Shape Grammar Implementation | Strobbe | 2013 |
| 19 | GRAPE: U12 and U13 SG Interpreter/[15] | Grasl & Economou | 2013 |
| 20 | GRAPE: Agent-based Rule Decision | Grasl & Economou | 2014 |
| 21 | ShaDe/[28] | Ruiz-Montiel | 2014 |
| 22 | SortAL GI | Dy & Stouffs | 2017 |

Still, despite the relatively large number of general-purpose shape grammar interpreters, the evidence of their impact in practice and academia does not readily support an optimistic state of affairs on the current state-of-the-art of the field. The very core values that their underlying shape grammar formalism has promised, the miraculous calculations with shapes, the visual treatment of emergence and ambiguity, the seamless interface in design workflows, are all still in want.

Thus, a need yet exists to take on these specific disadvantages, and it would be beneficial to propose a new computational technology built from scratch that fundamentally redefines the way shapes are represented, indexed, queried and operated upon. Such a novel approach would have its foregrounding of visual rules (shape rules drawn in a 2D or 3D modeling system) over symbolic rules (instructions defined in some programming language), providing a robust and disruptive technology for engineers, computer scientists, designers, students and educators, and in general academics and professionals who use drawings and visual models to develop and communicate their ideas. It is to such a computational technology that the present invention is primarily directed.

### BRIEF SUMMARY OF THE INVENTION

Briefly described, in an exemplary embodiment, the present invention comprises innovative computational technology that deals comprehensively with the issues plaguing conventional shape embedding and shape replacement in generative modelling, advancing at least six aspects in (i) a new system architecture to account for the modules and processes required for the automated embedding and replacement of shapes made up of lines; (ii) a calibration mechanism to address the issue of precision errors in CAD systems; (iii) a pictorial algorithm of shape embedding under perspectival transformations to deal effectively with the entire spectrum of linear transformations; (iv) a two-step mechanism to deal with indeterminate embedding; (v) a ranking system of registration points to improve shape embedding performance; and (vi) a layered system structure to achieve a seamless integration of rule definitions and applications in shape computation.

The present invention can be viewed as a foundation for the future development for supporting more shape types, and the shape embedding under the transformations beyond linear transformations in a 3D space other than 2D space only.

For nearly four decades, the shape grammar discourse has described a different paradigm of design computing with the promise of revolutionizing CAD. Its foregrounding of visual rules (shape rules drawn in a 2D or 3D modeling system) over symbolic rules (instructions defined in some programming language) has provided a robust theory for designers to believe in but nevertheless a formidable challenge to implement despite the best efforts of research groups at various schools and labs at MIT, CMU, ETH and elsewhere.

The present invention includes a software application that manages to successfully meet the challenges that separate the visual rules from their symbolic counterparts and offer an unprecedented framework for the computations envisioned by the academic community and the CAD users since the early seventies.

The present invention can be a plug-in implemented in Python within the modeling software Rhinoceros 5 by Robert McNeel and Associates. As discussed, core aspects of the present invention include a new implementation of the reduction rules, a set of algorithms that provide a unique description to every shape in terms of the smallest number of maximal elements that specify it; a new implementation of shape recognition for all shapes comprising straight lines, arcs and their combinations under all Euclidean transformations; and a new implementation of a rule compiler of shape modification for all shapes comprising straight lines, arcs and their combinations under all Euclidean transformations. These aspects are built upon with additional innovations in the field.

The present invention weaves the various innovative six aspects in order to compile shape rules drawn by users into an executable form and execute them to carry forward a shape computation. This disruptive visual technology fundamentally redefines our current foundations of CAD in terms of both representation and process and in terms of how we learn design and do design too. Likely users that would benefit from this technology include architects, engineers, computer scientists, students and educators, and in general designers of all sorts who use drawings and visual models to develop and communicate their ideas.

In order to properly contextualize the present invention, challenges that underly the implementation of a conventional shape grammar interpreter should be addressed.

A computer implementation of a shape computation requires the implementation of five distinct processes, all intimately involved in the recognition and replacement of a shape under a given transformation and all encoded in the structure of the shape algebras Uᵢⱼ that shape rules are defined in ([34]). More specifically, for u, v and W shapes, a shape rule u→v and the shape W defined as the current design, the operation that a shape grammar interpreter should process is:

if f(u)≤W:

W=W−f(u)+f(v) (1)

or, a) Encode the shapes u, v and W in the smallest number of basic elements that can specify them; b) Inquire whether there is transformation f that embeds the shape f(u) in W, and if yes; c) Subtract the shape f(u) from W; d) Add the shape f(v) in W; and e) Repeat the above processes for all applicable transformations of the shape f(u) in W. A visual example is shown in FIGS. 1A-1G to demonstrate five procedures outlined above underlying a shape replacement.

The example illustrated in FIGS. 1A-1G feature a shape rule applied under an isometric transformation, that is, a transformation that keeps shape and size invariant while varying handedness and position. In this case, there are eight f transformations that embed the shape f(u) in the shape W (that is, make the shape f(u) part of the shape W. FIGS. 1A-1G show a shape computation. FIGS. 1A-1C:Shapes u, v, and W; FIG. 1D: Shape rule u→v; FIG. 1E: Eight matches of the shape f(u) in W; FIG. 1F: Subtractions of the eight instances of the shape f(u) from W; FIG. 1G: Additions of the eight instances of the shape f(v) to the corresponding eight instances of the shape W−f(u).

The implementation of each of these five processes in a shape grammar interpreter brings its own set of problems and some more than others. A brief description of each process is given below.

The first process of encoding the shapes u, v and W in maximal representation, that is, in the smallest number of basic elements that can specify a shape ([34]), is to ensure that the shapes have a unique specification so that they can be compared and acted upon. The maximal representation of a shape is typically defined in different ways depending on the dimensionality of the shape, that is, 0-, 1-, 2- and 3-dimensions, and its type, that is, line, arc, conic, Bezier, etc., requiring in essence, different algorithms for a maximal point representation, maximal line representation, maximal curve representation, maximal plane representation, maximal surface representation, maximal solid representation, and so on ([34]). For most shape grammar implementations, the maximal representation of shape is implemented with various approaches and typically, by a combined usage of operations (computer programs) of shape instantiation and shape addition or shape subtraction ([23]). However, for more complex geometries, such as curves, surfaces, and solids, it is difficult to obtain the maximal representations of the corresponding elements of the shapes ([25]) and there is still a large number of shape types to be addressed. A different kind of problem might arise when shapes are perceptually similar but mathematically different and the implementation might seem to fail or otherwise cause confusion to users.

The second process of inquiring whether there is a transformation f that embeds the shape f(u) in W is the most critical—and elusive—process for most of the shape grammar interpreters. FIGS. 2A-2C illustrate the matching transformation, f is typically a Euclidean transformation—but more generally, a transformation belonging to the Euclidean, affine and projective geometries. FIGS. 2A-2C show types of linear transformations. FIG. 2A: Identity; FIG. 2B: Direct transformations (from left to right): Translation; Rotation; Scale; Stretch; Shear; One-point perspective; Two-point perspective; FIG. 2C: Indirect or handed versions of the transformations in FIG. 2B. Typically, a 3×3 matrix can be used to represent the transformations up to linear transformations, including isometric, similarity, affinity and perspectivity transformations, and the corresponding calculation of the transformations between two shapes in 2D space can be done by the derivation of a 3×3 matrix.

The third process of subtracting the shape f(u) from W is based on the detection of shape boundaries. [5] has listed 13 cases of two input lines with labeled endpoints so that the present system can derive the results with three different procedures. The implementation of shape subtraction for lines has been done by Krishnamurti ([22], [23]) and has been broadly adopted in other interpreters. However, this shape operation is highly related to shape types and the complexity of implementation increases as the dimensionality of shape and the corresponding dimensionalities of space that the shapes are defined in are both increasing too. As above, shape types captured by higher degrees might cause severe precision errors and make the system unstable. For instance, the calculation of descriptors of high degree curves such as Bezier curves can be heavy because the system has to resolve the coefficients of high degree polynomials ([19]).

The fourth process of adding the shape f(v) to W−f(u) is similar to subtracting. As above, [5] has listed out 13 cases of two input lines with labeled endpoints so that the present system can derive the results with three different procedures. Similarly, the implementation of shape addition for lines has been done by Krishnamurti ([22], [23]) and has been broadly adopted in other interpreters as well. The same problems that are encountered in the implementation of the subtraction operation are encountered here too.

The fifth process of repeating the above processes for all applicable transformations of the shape f(u) in W is straightforward for all shape grammar interpreter. The recursion can be implemented by re-assigning the result W−f(u)+f(v) from the previous iteration back to the same variable W for the next iteration. The formal expression can be written as:

W=W−f(u)+f(v) (2)

so that the result is:

W−Σ₀^{N-1}fᵢ(u)+Σ₀^{N-1}fᵢ(v) (3)

after N iterations, where fᵢ( ) represents the applied transformation for the i^{th} iteration.

The current shape grammar interpreters that have attempted to implement five processes outlined above have produced promising, albeit inconclusive results as to the generality of the adopted algorithms to determine visual queries and matches for all types of shapes and transformations under which the rules apply ([18]). It is suggested here that beyond a seemingly long list of technological hurdles that can undermine each of five processes outlined above, the implementation of shape embedding, that is, the implementation of the mathematical concept of the “part relation” between two shapes, or equivalently, between two drawings, or between a shape and a design, is the single major obstacle to take on.

The part relation (u≤W) between two shapes u and W in CAD systems is enabled by a database query requesting the retrieval and comparison of instances of shapes from a CAD database. Surprisingly, the visual embedding of shapes (shape query) under a given Euclidean, affine or linear transformation (f(u)≤W) is severely restricted from current CAD systems. This might come at a surprise when CAD geometry is intimately related to computational geometry—an ever-growing field of algorithms dealing with geometric problems involving operations on points, lines, planes and solids (see, for example, Preparata and Shamos 1985, Goodman and O'Rourke 1997). The impressive list of formal approaches on shape matching in computational geometry includes diverse shape representations such as CSG (constructive solid geometry), BSP (binary space partitioning) trees, octrees, B-rep (boundary representation), free form surfaces, implicit surfaces, and so on ([12]); diverse matching techniques such as tree pruning, pose clustering, geometric hashing, deformable templates, Fourier descriptors, wavelet transforms, neural networks, and so on ([2], [26], [3], [4]); and an expanding universe of classes of shapes to be compared including sketch-based shapes, non-rigid shapes, relief surface patches, multi-domain protein shapes, gesture sequence shapes, watertight models, and so forth ([39]). And yet, the single most important characteristic in all these approaches, the measurement of the similarity (or dissimilarity) of a shape with another shape using some appropriately constructed similarity or dissimilarity measure ([40]), is an indifferent measure when it comes to the notion of shape embedding under a given Euclidean, affine or linear transformation ([34]).

All shape grammar interpreters approach the problem in two ways, namely, by: a) the database query of the maximal elements that the shapes are made of, see for example, GRAPE ([15], [16]); Sortal ([35], [36]); and b) the derivation of the transformation matrix that embeds one shape into another, see for example, SGI ([22], [23]); SGS ([5]); GRAIL ([24]); GEdit ([37]). Both approaches rely on the formal descriptions of the maximal representation of shape and its registration marks or points ([30], [34], [21]). The implementation of shape embedding through database query, despite its success in well-structured cases and design workflows, fails to provide a general solution to the subshape problem ([27]). The implementation of shape embedding through the derivation of the transformation matrices is still the most promising method but it is plagued by a series of problems across several fronts ([35], [18]). A brief account of the problems and challenges underlying the implementation of shape embedding in shape grammar interpreters under a given transformation is given below.

Limited Support of the Dual Architecture of a CAD/Shape Grammar Interpreter

The successful calculation of the shape embedding is intimately related to the design of the architecture of the system and its ability to seamlessly integrate the shape embedding algorithms with either side of the system workflow of the shape computation, namely, the instantiation of shapes and shape rules, and their preview and applications in a CAD model to the users of the system. This relation between the CAD modeler and the shape embedding machine requires a dual architecture that has not been adequately addressed so far. Some of the challenges are given below.

Shapes and shape rules are instantiated with modeling tools either through available CAD systems, such as AutoCAD, 3DMax, MAYA, Rhinoceros, SketchUp, Revit, and so forth, through APIs for developers to implement their own components in these CAD systems, or entirely from scratch. Both approaches have their own challenges. Existing CAD systems have been adopted in the design practice for a long time and it is beneficial to implement a shape grammar interpreter within a CAD system to connect to designers' daily workflows. This model of implementation can be found in current interpreters, for instance, DESIGNA in AutoCAD ([9]), GRAPE in Rhinoceros ([14]), ShaDe in SketchUp ([28]) and so forth. This approach brings faster initial results but in the long run it is not scalable because the ways shapes are represented in CAD systems do not lend themselves to the computations required for shape embedding—see more below on the challenge of precision modeling. And clearly, developing a mature modeling tool from scratch requires much time and energy, for instance, SGI ([21], [23]), or GRAIL ([24]).

The integration of the workflow of shape embedding and replacement in current design processes continues to be a challenge. The system workflow of a shape computation in a shape grammar interpreter is typically divided into three main parts ([5]): 1) instantiation of shapes and shape rules; 2) calculation of shape embedding; and 3) preview and the application of shape rules.

Most of the shape grammar interpreters require users to jump back and forth between different windows, systems and files. For some interpreters ([22], [23], [5], Dy & Stouffs and [35]), the users have to “script” shapes in a text editor to define what shapes are applicable in the rule-based production. The process is not intuitive and requires a lot of effort to describe shapes. Even worse, only the shapes described in the script are supported in the computation and this reduces many opportunities to explore designs. Some interpreters ([37], Trescak et al. 2012, [15], [16]) provide users an interface to instantiate shapes and shape rules, however, the users need to draw shapes in a separate window or a subsystem. Furthermore, the geometric tools are not mature and often do not provide the precision required for the calculations with shapes required in shape grammar interpreters. It is disruptive in the design process if the designers need to switch between different windows, systems or files. Clearly, the seamless merge of a shape grammar interpreter into an existing design process is one more major task for development.

Precision Errors in Modeling

Precision error in CAD systems is a severe issue in shape computation. Technically, any computer implementation of a shape computation can only be viewed as an approximation, instead of a true shape computation system. There exists a natural gap between the continuum of geometries and the discreteness of digital infrastructure. Shapes represented as geometries such as points, lines, curves, are constructed on the real number system. However, digital environment (CAD systems) can only provide limited digits to represent real numerical values, thusly the precision errors commonly show up and accumulate in the computation. FIGS. 3A-3B show an example of the imperfection of geometries in CAD system. FIG. 3A: three endpoints of an equilateral triangle represented in an ideal cartesian plan; FIG. 3B: three endpoints of an equilateral triangle represented in a cartesian plan of CAD system with the resolution of 0.01 unit.

In general, precision errors can be ignored in the modeling process, since the precision errors in CAD system are typically smaller than the precision errors in manufacture processes. For instance, the EUV machine which is used to manufacture photomasks in semiconductor industries can only achieve the resolution of 8×10⁻⁹ meter (Schoot et al 2016) which is still larger than the resolution in CAD systems. Nevertheless, it is not allowed to have precision errors in shape computation as this type of computation is based on zero tolerance. For instance, a script written in Python programming language is shown as below:

if x==1:

x=x+1 (4)

The second line of the script (x=x+1) will not be executed even if x is 0.99999 or 1.00001; no matter how close the value of x is to 1.0: in all, precision errors are not allowed in shape computation. Additionally, rounding errors are often accumulated throughout the entire computation process from the instantiations of shapes, to the mechanisms checking the relationships among these shapes, and the shape Boolean operations required for the maximal representation of these shapes, rendering the computation process unstable and unreliable. The thirteen cases of spatial relations between two colinear lines that need to be checked to determine their possible fusion into a single maximal line are given in FIGS. 38A-38M.

Precision Errors in the Derivation of Transformations

The implementation of shape embedding under linear transformations, including isometric, similar, affine and perspectival ones, through the derivation of a 3×3 homography matrix requires complicated computations that often produce precision errors and incorrect matchings. These problems are especially exacerbated in the calculations of perspectival transformations.

More specifically, to derive a 3×3 isometry matrix that represents isometric transformations, two points from u and two points from W are required to resolve three unknown variables including the rotation angle θ, the translation vector in x direction tₓ and the translation vector in y direction t_{y} contained in the 3×3 matrix shown as below.

$$[ \begin{matrix}cosθ & sinθ & {t}_{x} \\ - sinθ & cosθ & {t}_{y} \\ 0 & 0 & 1\end{matrix} ] [ \begin{matrix}{x}_{{u}_{0}} \\ {y}_{{u}_{0}} \\ 1\end{matrix} ] = [ \begin{matrix}{x}_{{W}_{0}} \\ {y}_{{W}_{0}} \\ 1\end{matrix} ] \\ and \\ [ \begin{matrix}s \cdot cosθ & s \cdot sinθ & {t}_{x} \\ - s \cdot sinθ & s \cdot cosθ & {t}_{y} \\ 0 & 0 & 1\end{matrix} ] [ \begin{matrix}{x}_{{u}_{1}} \\ {y}_{{u}_{1}} \\ 1\end{matrix} ] = [ \begin{matrix}{x}_{{W}_{1}} \\ {y}_{{W}_{1}} \\ 1\end{matrix} ] \qquad ( 5 )$$

To derive a 3×3 similarity matrix that represents similarity transformations, two points from u and two points from W are required to resolve four unknown variables including the scaling factor s, the rotation angle θ, the translation vector in x direction tₓ and the translation vector in y direction t_{y} contained in the 3×3 matrix shown as below.

$$[ \begin{matrix}s \cdot cosθ & s \cdot sinθ & {t}_{x} \\ - s \cdot sinθ & s \cdot cosθ & {t}_{y} \\ 0 & 0 & 1\end{matrix} ] [ \begin{matrix}{x}_{{u}_{0}} \\ {y}_{{u}_{0}} \\ 1\end{matrix} ] = [ \begin{matrix}{x}_{{W}_{0}} \\ {y}_{{W}_{0}} \\ 1\end{matrix} ] \\ and \\ [ \begin{matrix}s \cdot cosθ & s \cdot sinθ & {t}_{x} \\ - s \cdot sinθ & s \cdot cosθ & {t}_{y} \\ 0 & 0 & 1\end{matrix} ] [ \begin{matrix}{x}_{{u}_{1}} \\ {y}_{{u}_{1}} \\ 1\end{matrix} ] = [ \begin{matrix}{x}_{{W}_{1}} \\ {y}_{{W}_{1}} \\ 1\end{matrix} ] \qquad ( 6 )$$

To derive a 3×3 affine matrix that represents up to affinity transformations, three points from u and three points from W are required to resolve seven unknown variables contained in the 3×3 matrix shown as below, where αₓ and α_{y} represent the stretching factor in x direction and y direction; φₓ and φ_{y} represent the shearing angle in x direction and y direction.

$$[ \begin{matrix}{α}_{x} \cdot cos θ + {α}_{y} \cdot sin θ \cdot tan {φ}_{y} & {α}_{x} \cdot cos θ + tan {φ}_{x} + {α}_{y} \cdot sin θ & {t}_{x} \\ - {α}_{x} \cdot sin θ + {α}_{y} \cdot cos θ \cdot tan {φ}_{y} & - {α}_{x} \cdot sin θ + tan {φ}_{x} + {α}_{y} \cdot cos θ & {t}_{y} \\ 0 & 0 & 1\end{matrix} ] [ \begin{matrix}{x}_{{u}_{0}} \\ {y}_{{u}_{0}} \\ 1\end{matrix} ] = [ \begin{matrix}{x}_{{W}_{0}} \\ {y}_{{W}_{0}} \\ 1\end{matrix} ] \qquad ( 7 )$$

The derivation of affine matrix can be simplified with six variables shown as below, where α₀₀=αₓ·cos θ+α_{y}·sin θ·tan φ_{y}, α₀₁=αₓ·cos θ·tan φₓ+α_{y}·sin θ, α₀₂=tₓ, α₁₀=−αₓ·sin θ+α_{y}·cos θ·tan φ_{y}, α₁₁=−αₓ·sin θ·tan φₓ+α_{y}·cos θ and α₁₂=t_{y}.

$$[ \begin{matrix}{a}_{00} & {a}_{01} & {a}_{02} \\ {a}_{10} & {a}_{11} & {a}_{12} \\ 0 & 0 & 1\end{matrix} ] [ \begin{matrix}{x}_{{u}_{0}} \\ {y}_{{u}_{0}} \\ 1\end{matrix} ] = [ \begin{matrix}{x}_{{W}_{0}} \\ {y}_{{W}_{0}} \\ 1\end{matrix} ] and [ \begin{matrix}{a}_{00} & {a}_{01} & {a}_{02} \\ {a}_{10} & {a}_{11} & {a}_{12} \\ 0 & 0 & 1\end{matrix} ] [ \begin{matrix}{x}_{{u}_{1}} \\ {y}_{{u}_{1}} \\ 1\end{matrix} ] = [ \begin{matrix}{x}_{{W}_{1}} \\ {y}_{{W}_{1}} \\ 1\end{matrix} ] \qquad ( 8 )$$

To derive a 3×3 homography matrix that represents up to linear transformations, four points from u and four points from W are required to derive nine unknown variables contained in the 3×3 matrix shown as below. The derivation of a planar homography matrix involves heavy calculations that might cause a precision problem because of the accumulation of rounding errors.

$$[ \begin{matrix}{a}_{00} & {a}_{01} & {a}_{02} \\ {a}_{10} & {a}_{11} & {a}_{12} \\ {a}_{20} & {a}_{21} & {a}_{22}\end{matrix} ] [ \begin{matrix}{x}_{{u}_{0}} \\ {y}_{{u}_{0}} \\ 1\end{matrix} ] = [ \begin{matrix}{x}_{{W}_{0}} \\ {y}_{{W}_{0}} \\ 1\end{matrix} ] and [ \begin{matrix}{a}_{00} & {a}_{01} & {a}_{02} \\ {a}_{10} & {a}_{11} & {a}_{12} \\ {a}_{20} & {a}_{21} & {a}_{22}\end{matrix} ] [ \begin{matrix}{x}_{{u}_{1}} \\ {y}_{{u}_{1}} \\ 1\end{matrix} ] = [ \begin{matrix}{x}_{{W}_{1}} \\ {y}_{{W}_{1}} \\ 1\end{matrix} ] \qquad ( 9 )$$

In all, the derivation of a 3×3 matrix works for all linear transformations, still, the heavy computation load, especially for perspectival transformations, causes severe precision errors which are not able to be recovered easily by calibration mechanisms.

Limited Support for Indeterminate Shape Embedding

The proper determination of whether a shape embedding is decidable (determinate) or not (indeterminate) and the proper mechanisms to help make an indeterminate embedding a determinate one, continue to be challenge. An embedding is determinate when a shape u can be embedded into a shape W in finite ways, that is, when there is a finite number of transformations that can make u embedded in W; and an embedding is indeterminate when a shape u can be embedded into a shape W in infinite ways, that is, when there is an infinite number of transformations that can make u embedded in W([30]). Alternatively, shape embedding is determinate when the shape u has an adequate number of registration marks or registration points to decide the transformation under which the embedding can be applied, and indeterminate otherwise (Stiny [30], [34]; Krishnamurti, [21], [22]).

The implementation of shape embedding for shapes featuring a lesser number of registration points than the one required for the derivation of the transformation matrix for a given transformation is indeterminate and cannot be computed as such. For instance, an embedding of a shape u into a shape W under a similar transformation requires two registration points from each shape, however, if u has less than two registration points, there will be insufficient information for the present system to derive the transformation matrix. FIGS. 4A-4F show an example of indeterminate embedding under a similar transformation where the left-hand-side shape u has one registration point. FIG. 4A: An instance of a parameterized shape g(U); FIG. 4B: Registration points R_{g(U)}; FIG. 4C: Shape W; FIG. 4D: Registration points R_{W}; FIG. 4E: The single embedding schema; FIG. 4F: Three instances of the single embedding schema with assignments s: 1, 0.5 and 0.25, one per row, and their equivalent embeddings by the actions of the symmetry group of the shape W. There are ten distinct cases of indeterminate embedding, namely, one per isometries, two for similarities, three for affinities, and four perspectivities, and they are all related to the number of missing registration points to test the embedding (Hong and Economou, forthcoming).

The ten indeterminate cases of shape embedding for shapes consisting of lines are shown in FIG. 39. The indeterminate cases are denoted by the label IND. The possible arrangements of hyperplanes for each category are given or each column.

Algorithmic Complexity

A major challenge in the automated implementation of the derivation of the transformation matrices is related with aspects of performance in shape recognition and embedding: The complexity of embedding follows the number of the registration points available in the current design W. The method of the 3×3 matrix allows the system to use two registration points to achieve a Euclidean transformation, thus, the complexity of the embedding under Euclidean transformations is O(n²) for n the number of the registration points of W. For affine transformations the complexity increases to O(n³), and for linear transformations the complexity increases to O(n⁴). For more on algorithmic complexity and the Big-O notation, see, for example, [8]. Unless this challenge is confronted, the performance of shape embedding will always be too low to be a practical application. An example is offered here to illustrate this case: FIGS. 5A-5B are an example showing that a large number of registration points appear in an architectural plan. The simple architectural plan that comprising 240 maximal lines and 1125 registration points including endpoints and intersection points.

The derivation of transformation matrices for a shape embedding under Euclidean transformations requires the automated comparison of at least two registration points sampled in the left-hand-side shape u vs. all the pairs of registration points in the design W. The derivation of transformation matrices for a shape embedding under affine requires the automated comparison of at least three registration points sampled in the left-hand-side shape u vs. all the triplets of registration points in the design W. Finally, the derivation of transformation matrices for a shape embedding under linear transformations requires the automated comparison of at least four registration points sampled in the left-hand-side shape u vs. all the quadruples of registration points in the design W.

There are C₂¹¹²⁵=632,250 candidates for the system to test if the embedding is processed under Euclidean transformations; C₃¹¹²⁵=23,672,250 candidates to test if the embedding is processed under affine transformations; and C₄¹¹²⁵≅6.6×10¹⁰ candidates to test if the embedding is processed under linear transformations.

Assuming each candidate takes 0.001 second to test, a shape embedding under Euclidean transformation in the example above will take users 633 seconds to process only for one rule application, 394 hours for a single embedding rule under an affine transformation, and 2.121 years for a single embedding rule under a perspectival transformation. Clearly, the improvement of the calculating speed of the computer is not the answer. Even in the case of shape embedding under a Euclidean transformation, it is difficult for designers to pause their design processes for ten minutes just to wait for the results of one shape rule application. Clearly, the performance of shape embedding needs to be dramatically improved for the shape grammar interpreters to be useful in design practice.

The present invention is an innovative computational technology that deals comprehensively with the issues plaguing shape embedding and shape replacement in generative modelling in CAD/CAM. The present invention comprises core concepts including: an innovative system architecture to account for the modules and processes required for the automated embedding and replacement of shapes made up of lines; a calibration mechanism to address the issue of precision errors in CAD systems; a pictorial derivation of shape embedding transformations to deal effectively with the entire spectrum of linear transformations; a multi-step mechanism to deal with indeterminate embedding; and a ranking system of registration points to improve shape embedding performance.

The present invention includes a maximal line translator module. In the current CAD environment, there is a gap between data representation of geometry and the shape that user sees. Shapes in the current CAD systems are described as objects and this data representation is irrelevant from the visual perception. The maximal line translator has been developed to translate any input geometry into a unique geometric representation, maximal line representation, which allows users to inquire this geometry in any way they want. The present maximal line translator is distinct from the Boolean union function, which is common in current CAD tools, because maximal line translator is based on visual perception, but the Boolean union function and all the other similar function is based on object-oriented structure.

Also, there were 72 implementations trying to achieve this function but most of them are based on object-oriented structure, in fact, the other implementations are mostly adopting the Boolean union functions available in CAD tools. The present maximal line translator revisits the fundamental structure of CAD system and proposed a new data representation which is based on what users see instead of what computer store in the database.

The present invention further includes a sub-shape recognition module. The sub-shape recognition module recognizes, matches and/or searches any sub-shape (part) within a bigger shape that can be seen by users but is not existing in the database of CAD systems. For most of the current CAD tools, a user can only access the shapes which are already objects registered in the database, however, there are infinite ways to re-describe shapes and users can always partition shape in a different way. The sub-shape recognition module is different from the image recognition which is a very important research topic nowadays. Image recognition technology is basically a pixel-based technology which requires a lot of data training (machine learning) and can only recognize the entire image and well-defined objects. If users want to use image recognition to search a small part of the image and this small part is not defined in any existing context, it will require a whole training process to train the computer to “search” the specific part that users want to search. A key difference is that pixel-based technology is not based on geometry (points, lines, planes, solids, etc.) so it will need a whole process of data training to help computer find out the structure behind the pixel data.

Moreover, designers (industrial design, interior design, architecture, urban design, 3D animation design, etc) are mostly working with CAD tools such AutoCAD, Rhinoceros, Solidworks, 3DMax, MAYA because these tools can provide an environment for designers to manipulate geometries instead of pixel-based images. Designer can create, edit, copy or transform geometries to achieve designs. However, the current CAD tools represent geometries in a very poor way for storage efficiency, these CAD tools use “object sets” to describe shapes and it causes a huge gap between visual perception and the data representation. So, designers can only manipulate the registered objects to create a design or edit a design. If users want to access some shapes which are not registered objects, there is no way to do it. This limitation of conventional CAD tools not only highly limits the creativity of designer, but also highly limits the possibility of inquiring visual models in other discourses, such as chemistry, electrical engineering, mechanical engineering, music, archaeology, computer science, mathematics, and physics. The present sub-shape recognition module is the first one which can manage this problem with a general solution.

These and other objects, features and advantages of the present invention will become more apparent upon reading the following specification in conjunction with the accompanying drawing figures.

### BRIEF DESCRIPTION OF THE DRAWINGS

The accompanying Figures, which are incorporated in and constitute a part of this specification, illustrate several aspects described below.

FIGS. 1A-1G show a shape computation. FIGS. 1A-1C: Shapes u, v, and W; FIG. 1D: Shape rule u→v; FIG. 1E: Eight matches of the shape f(u) in W; FIG. 1F: Subtractions of the eight instances of the shape f(u) from W; FIG. 1G: Additions of the eight instances of the shape f(v) to the corresponding eight instances of the shape W−f(u).

FIGS. 2A-2C show types of linear transformations. FIG. 2A: Identity; FIG. 2B: Direct transformations (from left to right): Translation; Rotation; Scale; Stretch; Shear; One-point perspective; Two-point perspective; FIG. 2C: Indirect or handed versions of the transformations in FIG. 2B.

FIGS. 3A-3B are an example of the precision errors of geometries in CAD systems. FIG. 3A: three endpoints of an equilateral triangle represented in an ideal cartesian plan; FIG. 3B: three endpoints of an equilateral triangle represented in a cartesian plan of CAD system with the resolution of 0.01 unit.

FIGS. 4A-4F are an example of indeterminate similar embedding using one registration point. FIG. 4A: An instance of a parameterized shape g(U); FIG. 4B: Registration points R_{g(U)};

FIG. 4C: Shape W; FIG. 4D: Registration points R_{W}; FIG. 4E: The single embedding schema;

FIG. 4F: Three instances of the single embedding schema with assignments s: 1, 0.5 and 0.25, one per row, and their equivalent embeddings by the actions of the symmetry group of the shape W.

FIGS. 5A-5B are an example showing that a large number of registration points appear in an architectural plan. FIG. 5A: An architectural plan comprising 240 maximal lines. FIG. 5B: 1125 registration points intersected by 240 maximal lines.

FIG. 6 is a block diagram of an illustrative computer system architecture 100, according to an exemplary embodiment.

FIG. 7 illustrates the present invention according to an exemplary embodiment, including six major components: 1) communication/control layer, 2) shape rule compiler, 3) design initialize, 4) maximal line modeler, 5) shape embedding engine, and 6) rule application unit.

FIG. 8 illustrates the modules of the communication/control layer component of the present shape machine.

FIG. 9 is a screenshot of the shape machine 200, the shape rule is shown in the dash-lined block including a left-hand-side shape comprising three maximal lines in an arrangement like a letter “K”, and a right-hand-side shape comprising three maximal lines in an arrangement like a letter “C”, and a rule template comprising seven maximal lines in an arrangement like a right arrow and two crosses. The shape on the right is a design comprising eight maximal lines in an arrangement like two nested squares. Note that the dashed lines and the captions “Shape Rule: and “Design” are added here for clarity and they are not part of the interface.

FIG. 10 illustrates the modules of the shape rule compiler component of the shape machine 200.

FIG. 11 illustrates the data structure of a shape comprising lines.

FIG. 12 illustrates the modules of the design initializer component of the shape machine 200.

FIGS. 13A-13B show the four channels of the maximal line modeler component and the corresponding three modules per channel respectively. FIG. 13A: maximal line modeler with four channels; FIG. 13B: One of the channels where three major functionalities are implemented.

FIGS. 14A-14B show data structures of the lines before and after the maximal line modeler. FIG. 14A: The data structure of lines before the maximal line modeler; FIG. 14B: The data structure of lines after the maximal line modeler.

FIG. 15 illustrates the modules of the shape embedding engine of the shape machine 200.

FIG. 16 illustrates the modules of the rule application unit of the shape machine 200.

FIG. 17 is an example that two lines are recognized as equal because the distance between two endpoints H_{A} and H_{B} is smaller than the tolerance dₜ and the distance between the endpoints T_{A} and T_{B} is smaller than the tolerance dₜ too.

FIGS. 18A-18B are an example of the line relationship where two lines are collinear and only one endpoint of l_{B} occurs between two endpoints of l_{A}. FIG. 18A: l_{A} and l_{B} are in this case of relation without any precision error; FIG. 18B: an imperfect instance of this case of relation where l_{A} and l_{B} are neither truly parallel nor truly collinear.

FIG. 19 is an example of the maximization of lines with a calibration where l_{A} and l_{B} are recognized as equal lines.

FIGS. 20A-20B are an example of the maximization for two lines with line relationship where two lines are collinear and only one endpoint of l_{B} occurs between two endpoints of l_{A}. FIG. 20A: An example of maximization without any precision error where l_{A} and l_{B} are both removed and a new maximal line with endpoints H_{A} and T_{B} is created; FIG. 20B: An example of maximization with precision errors where l_{A} and l_{B} are both removed and a new maximal line with endpoints H′ and T′ is created.

FIGS. 21A-21B are an example of the Boolean difference l_{A}−l_{B} where l_{B} is embedded in l_{A} and none of the endpoints of l_{B} coincides with any endpoint of l_{A}. FIG. 21A: An example of Boolean difference without any precision error where l_{A} and l_{B} are both removed and two new maximal lines l′₁ with endpoints H_{A} and H_{B} and l′₂ with endpoints T_{B} and T_{A}, are created; FIG. 21B: An example of Boolean difference with precision errors where l_{A} and l_{B} are both removed and two new maximal lines l′₁ with new endpoints H′₁, T′₁ and l′₂ with new endpoints H′₂, T′₂ are created.

FIGS. 22A-22F illustrate the six geometric operations simulated in the present invention. (FIG. 22A) Constructing an arbitrary hyperplane through a given point; (FIG. 22B) constructing a hyperplane with two given points; (FIG. 22C) finding a point of intersection of two given non-parallel hyperplanes; (FIG. 22D) constructing a hyperplane parallel to a given hyperplane through a given point which is out of the given hyperplane; (FIG. 22E) constructing a hyperplane perpendicular to a given hyperplane through a given point; (FIG. 22F) given two points p₁ and p₂, constructing a point p′ on a given hyperplane h′ with a given point p on h′ and let p̅′̅p̅=p̅₁̅p̅₂̅.

FIGS. 23A-23B illustrate an example of a pictorial derivation of a linear transformation through the construction of a projective congruent spatial relation between two pairs of five points. (FIG. 23A) A point p with four registration points r₁, r₂, r₃ and r₃ as the references; (FIG. 23B) The four targeted registration points r′₁, r′₂, r′₃ and r′₄.

FIG. 24 illustrates step 1 to step 25 of the pictorial approach to derive the transformation for shape embedding under a linear transformation.

FIG. 25 illustrates step 26 to step 49 of the pictorial approach to derive the transformation for shape embedding under a linear transformation.

FIGS. 26A-26D illustrate four results of the pictorial approach for the derivation of linear transformation.

FIGS. 27A-27D are an example of registration point embedding. FIG. 27A: a design W comprising 12 maximal lines embedded in 12 hyperplanes; FIG. 27B: among 36 registration points at which 12 hyperplanes intersect, eight of them (highlighted by circles) are able to contain the two registration points (highlighted by circles in (FIG. 27D)) of u; FIG. 27C: a shape u comprising six maximal lines embedded in six hyperplanes; FIG. 27D: eight registration points at which six hyperplanes intersect, among these registration points, two of them (highlighted by circles) can be only embedded in the eight of the registration points (highlighted by circles in (FIG. 27B)) of W.

FIG. 28 illustrations the eight results of embedding under similar transformation of the previous example. The two sampled registration points of u can only be embedded in the eight selected registration points of W.

FIGS. 29A-29B are an example of weighting process of a registration point when all lines share identical attributes. FIG. 29A: A shape comprising ten maximal lines embedded in four hyperplanes and FIG. 29B: one of the registration points intersected by eight maximal lines embedded in three hyperplanes.

FIGS. 30A-30C show three configurations of a maximal line and a registration point. FIG. 30A: the first configuration c₁ that the registration point is not occurring on the maximal line; FIG. 30B: the second configuration c₂ that the registration point is occurring on the endpoint of the maximal line; FIG. 30C: the third configuration c₃ that the registration point is occurring on the body of the maximal line.

FIGS. 31A-31C are an example of normalized maximal lines intersecting at the registration point in FIG. 26B. FIG. 31A: three normalized maximal lines embedded in the hyperplane h₁; FIG. 31B: two normalized maximal lines embedded in the hyperplane h₂; FIG. 31C: three normalized maximal lines embedded in the hyperplane h₄.

FIGS. 32A-32H show the simplest form of the normalized maximal lines intersecting at the registration point in FIG. 29 and its seven supersets. FIG. 32A: The simplest form of the normalized maximal lines intersecting at the registration point; FIGS. 32B-32H: seven supersets of the normalized weight of the registration point.

FIG. 33 is a visual explanation of the data representation of the weight of the registration point.

FIGS. 34A-34B are an example of a registration point r_{B} at which four hyperplanes intersect and the weight is a superset of the weight of the registration point in FIG. 29. FIG. 34A: a registration point at which six maximal lines embedded in four hyperplanes intersect; FIG. 34B: the normalized form of registration point r_{B}.

FIGS. 35A-35D illustrate that the system checks if it is possible to embed r_{A} into r_{B} by checking the weights in a cyclic manner. For example, the system checks if the first item of the w_{A}

$$( [ \begin{matrix}{c}_{1} \\ {c}_{2}\end{matrix} ] )$$

is a subset of the item of the w_{B} with the smallest index. After fitting the first item into w_{B}, the system starts to fit the second item into w_{B}.

FIGS. 36A-36C are an example of embedding a normalized registration point into another normalized registration point. FIG. 36A: a normalized registration point at which five normalized maximal lines embedded in three hyperplanes intersect; FIG. 36B: a normalized registration point at which six normalized maximal lines embedded in four hyperplanes intersect; FIG. 36C: the result of embedding.

FIG. 37 is a flowchart of the calculation of shape embedding of the shape machine 200. Those dash-lined blocks represent that the operations are process in the CAD systems, in this work, the CAD system adopted is McNeel Rhinoceros 5.0 or above.

FIGS. 38A-M illustrate thirteen cases for two collinear lines. FIGS. 38A, 38B Two cases where two lines do not intersect; FIGS. 38C, 38D Two cases where two lines intersect at endpoints; FIGS. 38E, 38H Two cases where the intersection of the two lines is a part of both lines; FIGS. 38F, 38G Two cases where the intersection of the two lines is the line l_{B} with the alignment of one endpoint; FIG. 38I The case where the intersection of two lines is l_{B} and no endpoint is aligned; FIG. 38J The case where two lines are equal; FIG. 38K The case where the intersection of two lines is l_{A} and no endpoint is aligned; FIGS. 38L, 38M Two cases where the intersection of two lines is l_{A} with the alignment of one endpoint.

FIG. 39 is a table illustrating fourteen cases of shape embedding for shapes consisting of lines.

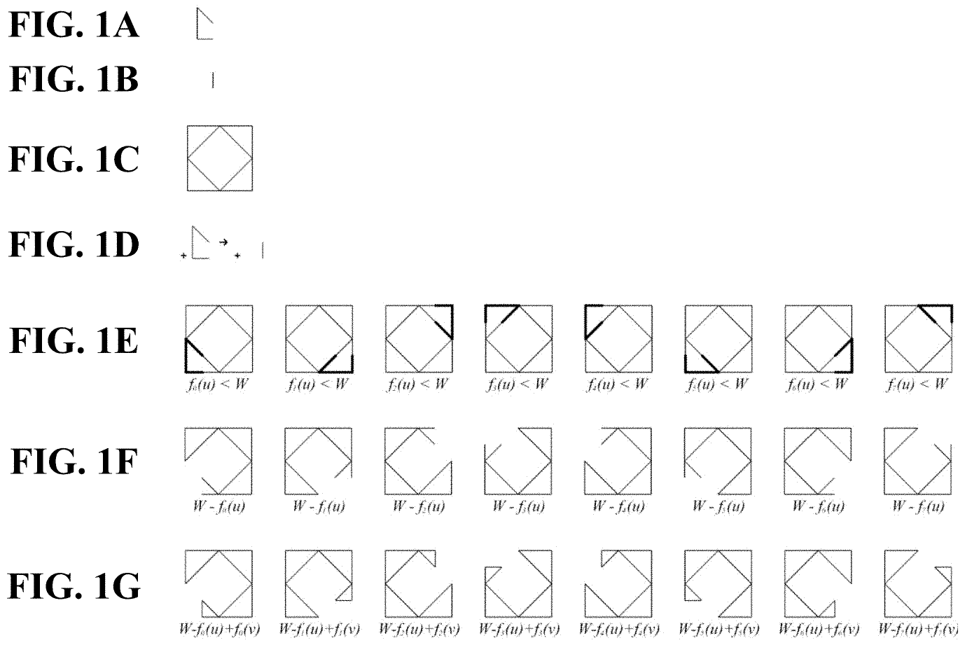

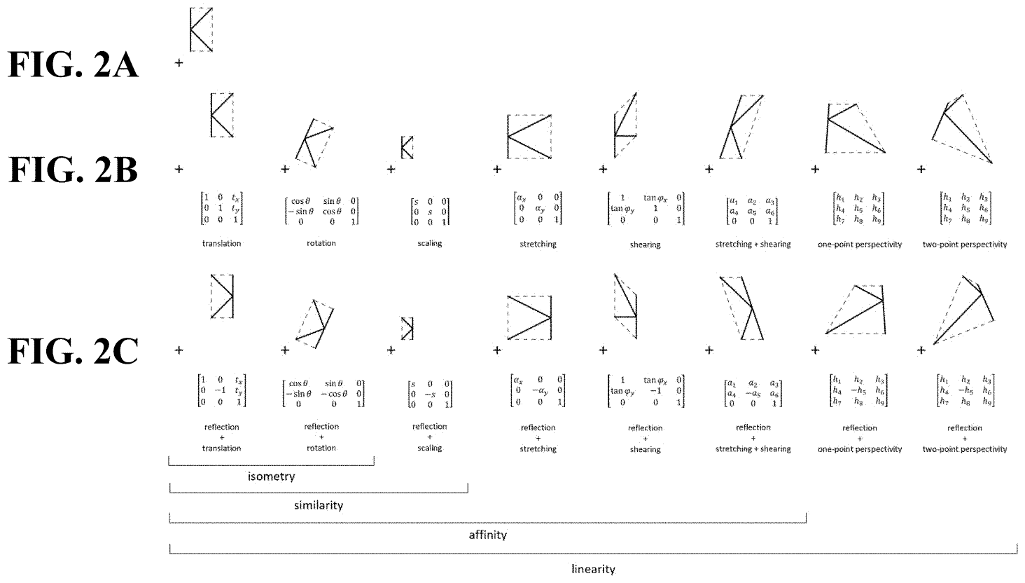

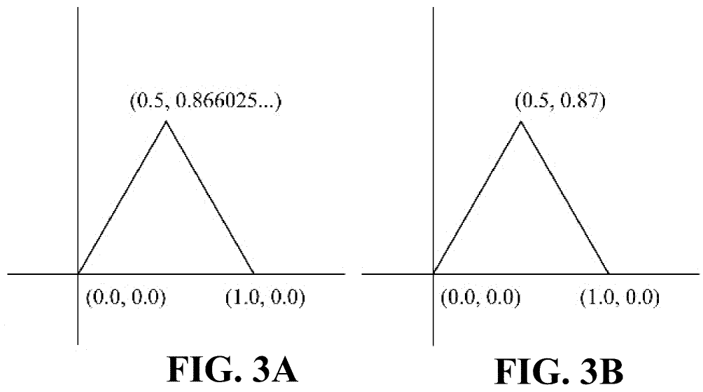

### DETAILED DESCRIPTION OF THE INVENTION

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Using “comprising” or “including” or like terms means that at least the named compound, element, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

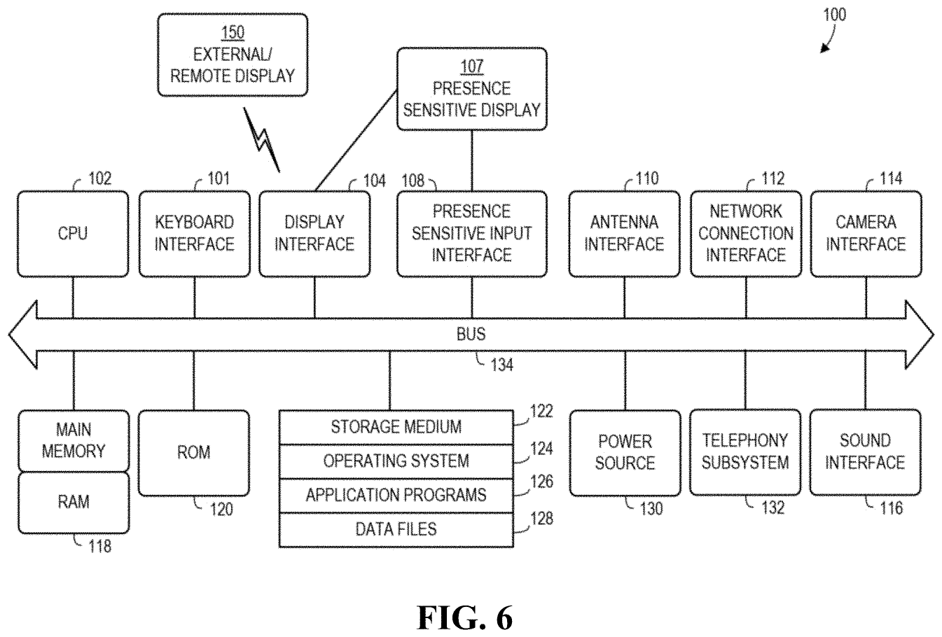

Aspects of the disclosed technology may be implementing using at least some of the components illustrated in the computing device architecture 100 of FIG. 6. As shown, the computing device architecture includes a central processing unit (CPU) 102, where computer instructions are processed; a display interface 104 that acts as a communication interface and provides functions for rendering video, graphics, images, and texts on the display. In certain example implementations of the disclosed technology, the display interface 104 may be directly connected to a local display, such as a touch-screen display associated with a mobile computing device. In another example implementation, the display interface 104 may be configured for providing data, images, and other information for an external/remote display that is not necessarily physically connected to the mobile computing device. For example, a desktop monitor may be utilized for mirroring graphics and other information that is presented on a mobile computing device. In certain example implementations, the display interface 104 may wirelessly communicate, for example, via a Wi-Fi channel or other available network connection interface 112 to the external/remote display.

In an example implementation, the network connection interface 112 may be configured as a communication interface and may provide functions for rendering video, graphics, images, text, other information, or any combination thereof on the display. In one example, a communication interface may include a serial port, a parallel port, a general purpose input and output (GPIO) port, a game port, a universal serial bus (USB), a micro-USB port, a high definition multimedia (HDMI) port, a video port, an audio port, a Bluetooth port, a near-field communication (NFC) port, another like communication interface, or any combination thereof. In one example, the display interface 104 may be operatively coupled to a local display, such as a touch-screen display associated with a mobile device. In another example, the display interface 104 may be configured to provide video, graphics, images, text, other information, or any combination thereof for an external/remote display that is not necessarily connected to the mobile computing device. In one example, a desktop monitor may be utilized for mirroring or extending graphical information that may be presented on a mobile device. In another example, the display interface 104 may wirelessly communicate, for example, via the network connection interface 112 such as a Wi-Fi transceiver to the external/remote display.

The computing device architecture 100 may include a keyboard interface 106 that provides a communication interface to a keyboard. In one example implementation, the computing device architecture 100 may include a presence-sensitive display interface 108 for connecting to a presence-sensitive display 107. According to certain example implementations of the disclosed technology, the presence-sensitive display interface 108 may provide a communication interface to various devices such as a pointing device, a touch screen, a depth camera, etc. which may or may not be associated with a display.

The computing device architecture 100 may be configured to use an input device via one or more of input/output interfaces (for example, the keyboard interface 106, the display interface 104, the presence sensitive display interface 108, network connection interface 112, camera interface 114, sound interface 116, etc.,) to allow a user to capture information into the computing device architecture 100. The input device may include a mouse, a trackball, a directional pad, a track pad, a touch-verified track pad, a presence-sensitive track pad, a presence-sensitive display, a scroll wheel, a digital camera, a digital video camera, a web camera, a microphone, a sensor, a smartcard, and the like. Additionally, the input device may be integrated with the computing device architecture 100 or may be a separate device. For example, the input device may be an accelerometer, a magnetometer, a digital camera, a microphone, and an optical sensor.

Example implementations of the computing device architecture 100 may include an antenna interface 110 that provides a communication interface to an antenna; a network connection interface 112 that provides a communication interface to a network. As mentioned above, the display interface 104 may be in communication with the network connection interface 112, for example, to provide information for display on a remote display that is not directly connected or attached to the system. In certain implementations, a camera interface 114 is provided that acts as a communication interface and provides functions for capturing digital images from a camera. In certain implementations, a sound interface 116 is provided as a communication interface for converting sound into electrical signals using a microphone and for converting electrical signals into sound using a speaker. According to example implementations, a random-access memory (RAM) 118 is provided, where computer instructions and data may be stored in a volatile memory device for processing by the CPU 102.

According to an example implementation, the computing device architecture 100 includes a read-only memory (ROM) 120 where invariant low-level system code or data for basic system functions such as basic input and output (I/O), startup, or reception of keystrokes from a keyboard are stored in a non-volatile memory device. According to an example implementation, the computing device architecture 100 includes a storage medium 122 or other suitable type of memory (e.g. such as RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives), where the files include an operating system 124, application programs 126 (including, for example, a web browser application, a widget or gadget engine, and or other applications, as necessary) and data files 128 are stored. According to an example implementation, the computing device architecture 100 includes a power source 130 that provides an appropriate alternating current (AC) or direct current (DC) to power components.

According to an example implementation, the computing device architecture 100 includes and a telephony subsystem 132 that allows the device 100 to transmit and receive sound over a telephone network. The constituent devices and the CPU 102 communicate with each other over a bus 134.

According to an example implementation, the CPU 102 has appropriate structure to be a computer processor. In one arrangement, the CPU 102 may include more than one processing unit. The RAM 118 interfaces with the computer bus 134 to provide quick RAM storage to the CPU 102 during the execution of software programs such as the operating system application programs, and device drivers. More specifically, the CPU 102 loads computer-executable process steps from the storage medium 122 or other media into a field of the RAM 118 in order to execute software programs. Data may be stored in the RAM 118, where the data may be accessed by the computer CPU 102 during execution. In one example configuration, the device architecture 100 includes at least 98 MB of RAM, and 256 MB of flash memory.

The storage medium 122 itself may include a number of physical drive units, such as a redundant array of independent disks (RAID), a floppy disk drive, a flash memory, a USB flash drive, an external hard disk drive, thumb drive, pen drive, key drive, a High-Density Digital Versatile Disc (HD-DVD) optical disc drive, an internal hard disk drive, a Blu-Ray optical disc drive, or a Holographic Digital Data Storage (HDDS) optical disc drive, an external mini-dual in-line memory module (DI MM) synchronous dynamic random-access memory (SDRAM), or an external micro-DI MM SDRAM. Such computer readable storage media allow a computing device to access computer-executable process steps, application programs and the like, stored on removable and non-removable memory media, to off-load data from the device or to upload data onto the device. A computer program product, such as one utilizing a communication system may be tangibly embodied in storage medium 122, which may comprise a machine-readable storage medium.

According to one example implementation, the term computing device, as used herein, may be a CPU, or conceptualized as a CPU (for example, the CPU 102 of FIG. 6). In this example implementation, the CPU may be coupled, connected, and/or in communication with one or more peripheral devices, such as display. In another example implementation, the term computing device, as used herein, may refer to a mobile computing device such as a smartphone, tablet computer, or smart watch. In this example embodiment, the computing device may output content to its local display and/or speaker(s). In another example implementation, the computing device may output content to an external display device (e.g., over Wi-Fi) such as a TV or an external computing system.

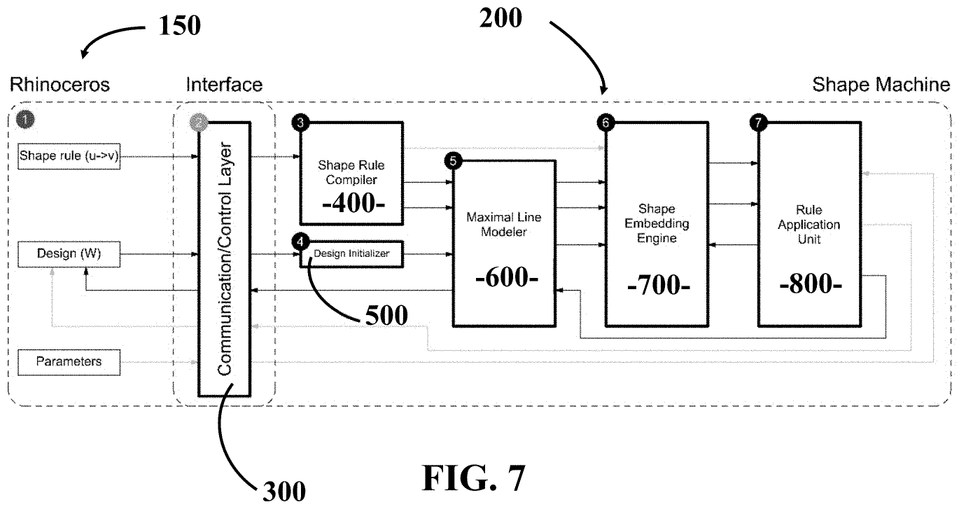

In an exemplary embodiment of the present invention, the engine proposed to perform the calculations required for the shape embedding and replacement (and distinct from the calculations required by a CAD modeling system for the selection, instantiation, transformation and combination of shapes in a CAD workflow). The relationship between the CAD modeler and the present invention is based on a modular and layered structure whereas data is transferred back and forth between the CAD Modeler and the present invention for multiple iterations. The dual architecture of the entire system is shown in FIG. 7. Note that the left dash-lined box represents the CAD system where users instantiate shapes, shape rules and input parameters, and the right dash-lined box represents the present invention where the shape rule and design are used as input for shape calculations.

The system structure of the shape machine 200 is shown in FIG. 7 and includes six major components: communication/control layer 300, shape rule compiler 400, design initializer 500, maximal line modeler 600, shape embedding engine 700, and rule application unit 800. The left dash-lined box represents the CAD system 150 where users instantiate shapes, shape rules and input parameters, and the right dash-lined box represents the present shape machine 200 where the shape rule and design are input.

Communication/Control Layer 300

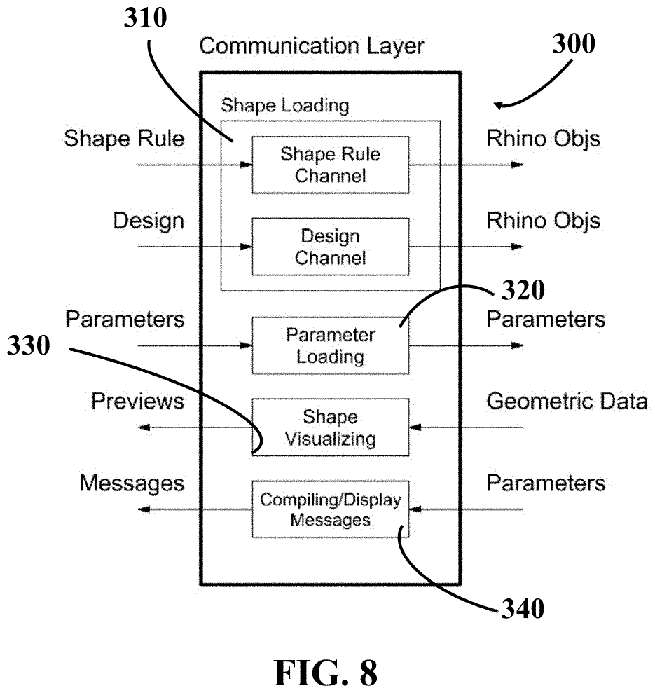

The communication/control layer 300 is a component between the kernel of the shape machine 200 and the CAD system 150, which includes four major procedures as shown in FIG. 8: loading shapes 310, loading parameters 320, visualizing previews 330, and compiling/displaying messages 340.

The first procedure 310, shape loading, loads the shapes into the shape machine 200, including the shape rules, u→v and the design W which are in the format defined by CAD system 150. This procedure 310 is implemented with the API of the CAD system, because the data representations of shapes vary from one CAD system to another CAD system.

The second procedure 320, parameter loading, loads the settings typically represented as integers into the shape machine 200 for users to communicate/control the shape machine 200. This procedure 320 is also implemented with the API of the CAD system and it is linked to a communication component of the CAD system, such as a prompt window where the CAD system shows message and information to users.

The third procedure 330, visualizing preview, instantiates shapes on the canvas as another communication mode. For example, if there are multiple results of a shape rule application, the shape machine 200 will send the results in numerical format to this layer and the results will be visualized directly on the design for the users.

The fourth procedure 340, Compiling/Message display, compiles the results and shows a message to the user according to the status of the shape machine 200. For instance, if the shape embedding is indeterminate, the shape machine 200 will show the ranges of parameters to the users and will ask for further information from them. Briefly, the communication/control layer 300 is responsible for the bidirectional communication with users via the CAD system 150.

The procedures 300, 400, 500, 600, 700 and 800 are implemented in a layered structure to avoid multiple windows or subsystems as the shape machine 200 is running behind the CAD system and communicates with users via the CAD system. For example, when users are using the tools of a CAD system to send parameters or input shape and shape rules to the shape machine 200, the shape machine 200 sends messages to users via a prompt window of the CAD modeler, or, it directly uses the geometric tools of the CAD modeler to create shapes on the canvas to convey the information. Because of this structure, shape rules can be drawn as any other shapes in CAD systems with a given rule template.

The rule template is a predefined shape in the CAD Modeler, however, a shape template is like any other shape in the CAD Modeler that consists of lines only. The difference of the rule templates from other shapes is that rule templates are assigned to a special layer “template” so that the shape machine 200 can detect the rule template. Furthermore, the parameters of rule application can be attached to the template and the present invention can load the information from the template, so that the interface can be more compact. The rule template itself consists of seven maximal lines that fix the conventions of a rule application: two pairs of lines in the form of a cross “+” signifying an origin point in the Euclidean plane, and three lines in the form of an arrow “→” signifying the separation between the left- and the right-had side shape. Note that shape rules and design are in the same canvas, so that the users can instantiate shapes rules by simply instantiating shapes or copying them from the current design in the canvas and pasting them in the shape rule template. This process is seamless and does not require any complex operations, say, importing shape rules modeled in another modeling application or writing scripts in some programming language to declare them. Note that shape rules and design are in the same canvas, so that the users can instantiate shapes rules by simply instantiating shapes or copying them from the current design in the canvas and pasting them in the shape rule template. This process is seamless and does not require any complex operations, say, importing shape rules modeled in another modeling application or writing scripts in some programming language to declare them.

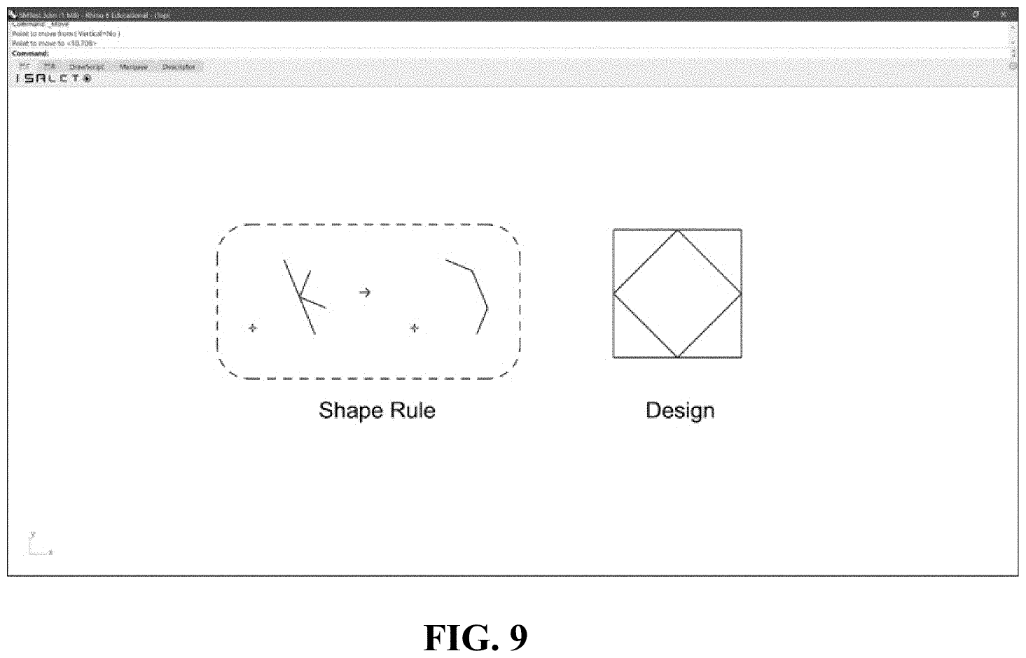

An example of a rule application in a particular instance of a CAD modeler (Rhinoceros) is shown in FIG. 9. To apply a shape rule, users click the button in a toolbar on the top of window shown in FIG. 9 to activate the shape machine 200. After activating the shape machine 200, the system is in a shape computation mode and waits from the users to select the shape rule on canvas with the rectangular selection tool provided by Rhinoceros. After the selection of a shape rule, the system compiles the shape rules and asks users to select the design where the shape rule will be applied. The selection of the design follows the same user-interaction conventions as in the selection of shape rule with the rectangular selection tool provided by Rhinoceros. After the selection of design, the system starts to process the shape rule application, calculates all possible matches and shows the previews upon the design on the canvas. Since the results of the shape computations are previewed on screen on the same canvas with the design, the users do not need to shift to other windows or systems back and forth.

The rule template is a predefined shape in Rhinoceros, however, a shape template is like any other shape in Rhinoceros that comprises only of lines. The difference of the rule templates from other shapes is that rule templates are assigned to a special layer “template” so that the shape machine 200 can detect the rule template. Furthermore, the parameters of rule application can be attached to the template and the shape machine 200 can load the information from the template, so that the interface can be more compact.

FIG. 9 is a screenshot of the shape machine 200, the shape rule is shown in the dash-lined block including a left-hand-side shape comprising three maximal lines in an arrangement like a letter “K”, and a right-hand-side shape comprising three maximal lines in an arrangement like a letter “C”, and a rule template comprising seven maximal lines in an arrangement like a right arrow and two crosses. The shape on the right is a design comprising eight maximal lines in an arrangement like two nested squares.

Shape Rule Compiler 400

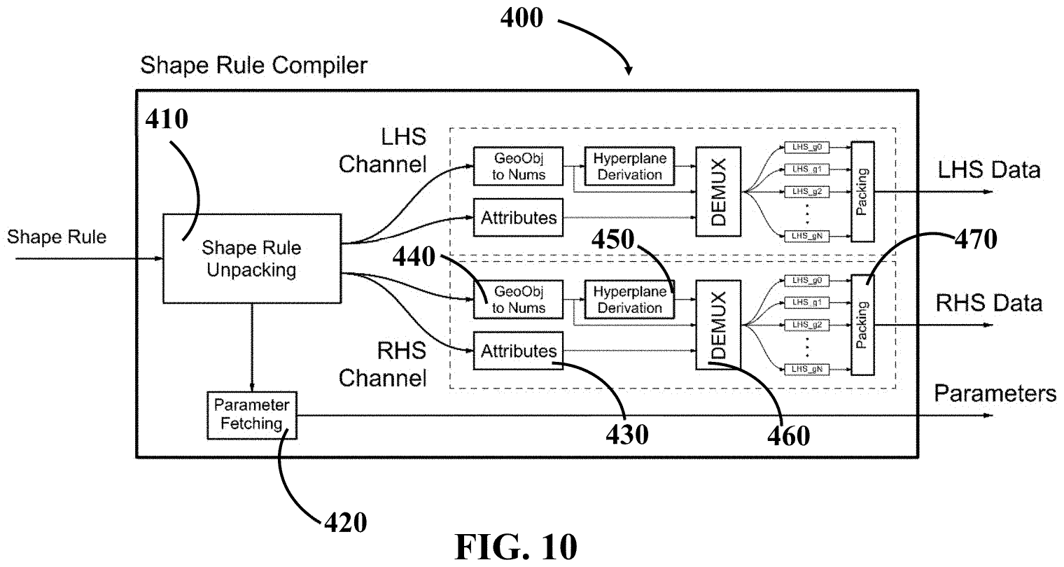

The shape rule compiler 400 shown in FIG. 10 translates the shape rule into the shape machine 200 format. There are seven functionalities in the shape rule compiler: shape rule unpacking 410, parameter fetching 420, attribute fetching 430, endpoint extraction 440, hyperplane derivation 450, hyperplane attachment 460, and data packaging 470.

After a shape rule is input into the shape rule compiler 400 from the communication/control layer 300, the first procedure 410, shape rule unpacking, unpacks the shape rule into three parts: the left-hand-side shape u, the right-hand-side shape v and the shape rule template.

The second procedure 420, parameter fetching, extracts the transformation parameters from the rule template.

The third procedure 430, attribute fetching, extracts the attributes from each line, namely, name (string), layer (string), color (as a three-integer vector), line type (string), and line width (integer), and attaches them as a part of the data representation.

The fourth procedure 440, endpoint extraction, extracts the coordinates of the endpoints of each line and translates the data format of both shape u and shape v from CAD objects to endpoint coordinates in the form of pure numerical values.

The fifth procedure 450, hyperplane derivation, calculates the hyperplane for each line, and the sixth procedure 460, hyperplane grouping, attaches the hyperplane to the data representation as a vector with three floating point numbers.

Finally, the seventh procedure 470, data packaging, packages the coordinates, the hyperplanes, and the attributes for both shape u and shape v in the form given in Table II.

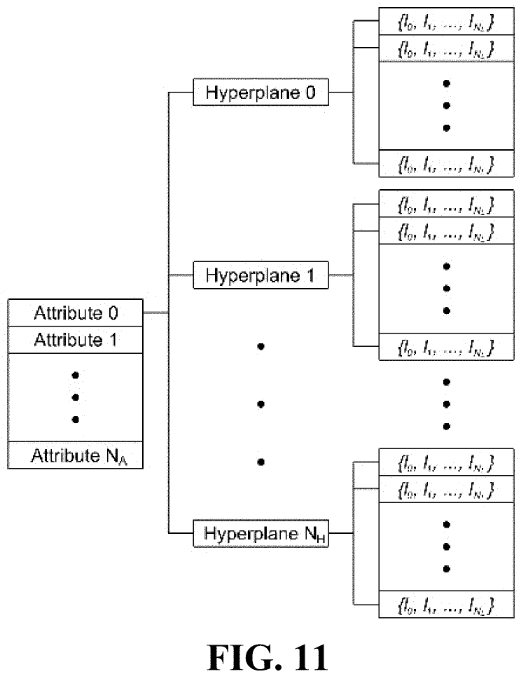

TABLE II
Data Representation Of A Maximal Line in a Shape

| Attribute | Hyperplane | Endpoints of line |
|---|---|---|
| { [Name, Layer, (r, g, b), Line | [a, b, c]; | [(x_{H}, y_{H}, z_{H}), (x_{T}, y_{T}, z_{T})] } |
| type, Print width]; | | |

[5] defined a data structure of a shape comprising lines grouped according to the hyperplanes where they are embedded. The same idea is adopted here to organize the data structure of a shape comprising lines whereas all lines are grouped according to their attributes and the hyperplanes they are embedded in. (FIG. 11)

Design Initializer 500

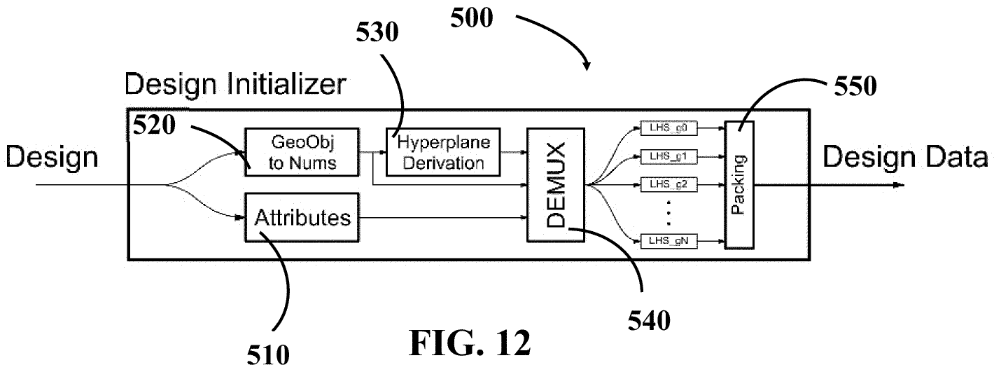

The design initializer 500 functions as a shape rule compiler 400 and is shown in FIG. 10. As shown in FIG. 12, the procedures of the design initializer 500 are: fetching the attributes from each line 510, extracting the coordinates of the endpoints of each line 520 and, deriving the hyperplanes for all the lines 530, grouping the data of lines according to attributes and hyperplanes 540, and packaging the coordinates, the hyperplanes and the attributes 550.

After processing all the procedures in design initializer 500, the data format of design W is translated from CAD objects to endpoint coordinates, which are pure numerical values. Meanwhile, the attributes of lines, which are name (string), layer (string), color (as a three-integer vector), line type (string), and line width (integer), will be extracted and attached as a part of the data representation. After the attributes and the endpoint coordinates extracting, the system calculates the hyperplane for each line and attaches the hyperplane to the data representation where a hyperplane is represented as a vector with three floating point numbers. The data representation of a line follows the exact same format given in Table II.

Maximal Line Modeler 600

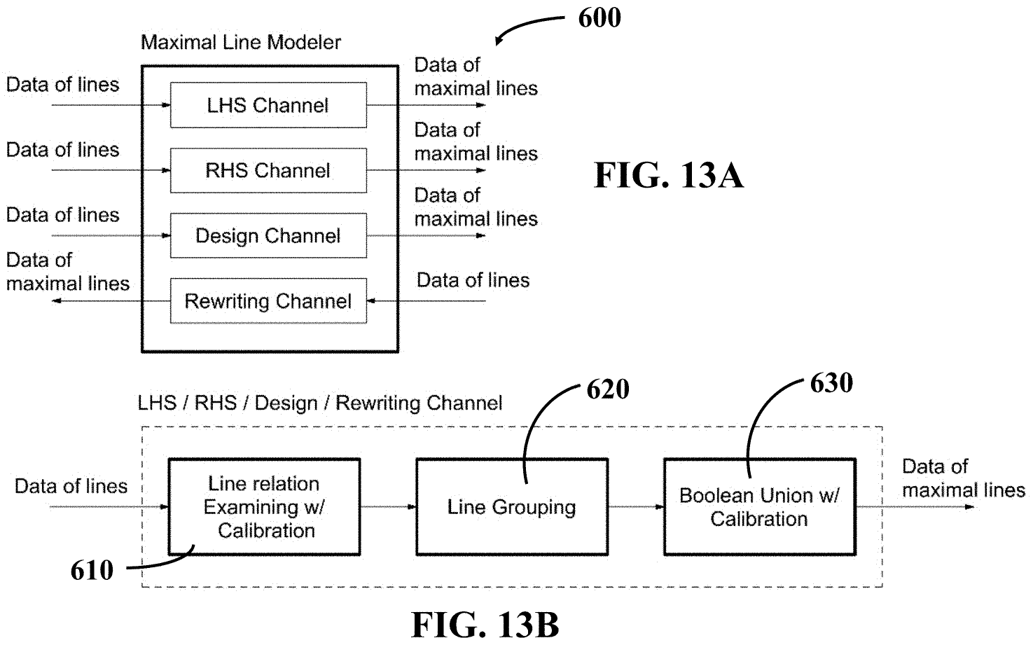

After the shape rule compiler 400, the data of the line elements of the shape u, shape v and design W are sent to maximal line modeler 600 with calibration to translate them into maximal line representation. In the maximal line modeler 600, there are three major functionalities: checking line relationships 610, grouping lines that should be merged 620, and Boolean union the lines within groups with calibration 630. FIG. 13A shows the four channels processing the data for shape u, shape v, design W and the revised design W′ respectively. The diagram of one of the channels of maximal line modeler is shown in FIG. 13B.

The three channels, LHS, RHS and design channel input data from the CAD system 150 and output the data of maximal lines to the shape embedding engine. The fourth channel, rewriting channel, is reversed because it is used to maximize the lines after shape rule application and output the data back to the CAD system. The fourth channel is used to make sure all the lines are in maximal representation before being sent back to the CAD system.

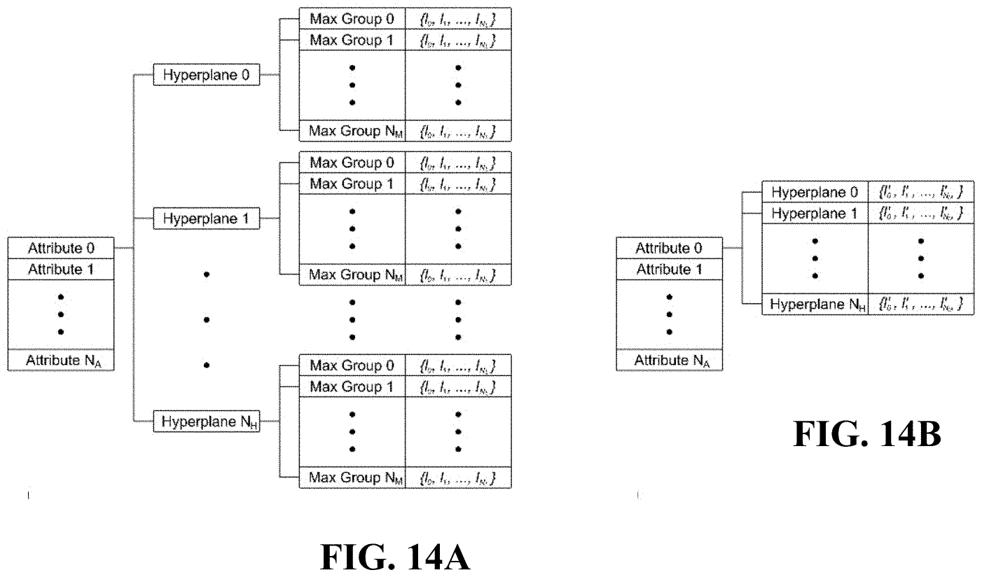

In each channel, lines in groups are sent to the first procedure where any two lines are examined with calibration. If two lines are in the relationship that they should be merged, the system labels them with each other's line index. After labeling, the second procedure is to group all the lines that should be merged. Note that lines are grouped again within attribute groups and hyperplane groups. In other words, each line is labeled with the hyperplane where it is embedded and the attributes of it. Thusly, the data format can be represented as a hierarchical structure shown in FIG. 14. FIGS. 14A-14B show data structures of the lines before and after the maximal line modeler. FIG. 14A: The data structure of lines before the maximal line modeler; FIG. 14B: The data structure of lines after the maximal line modeler. For the lines in each Max Group, they will be Boolean union in the third procedure and turn into one maximal line. The data representation of the lines after the maximal line modeler remains the same as in Table II.

Shape Embedding Engine 700

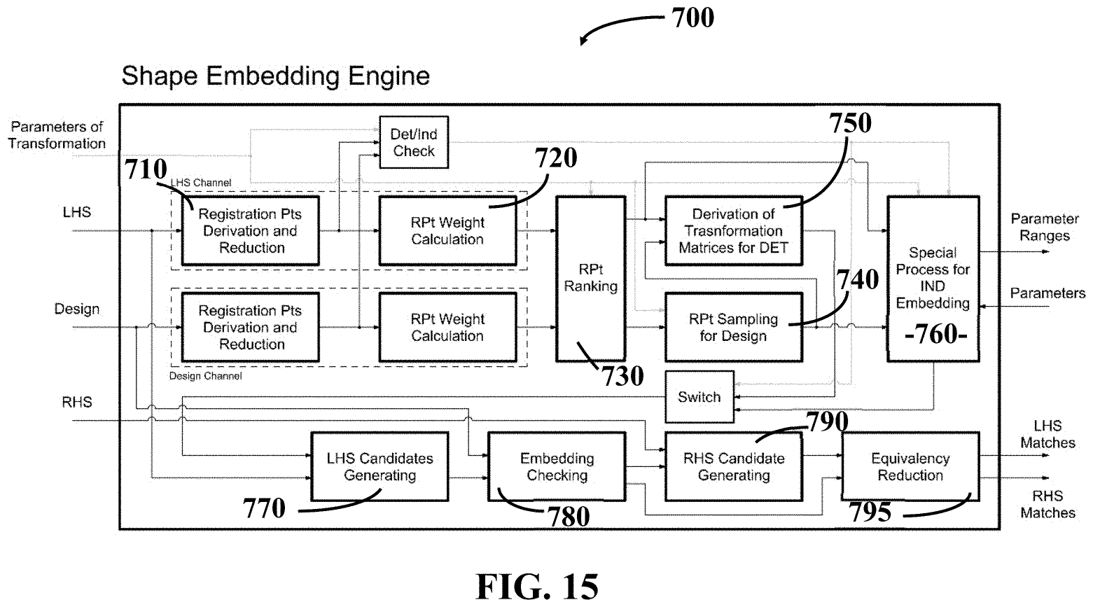

The shape embedding engine 700 is the most complicated component in the shape machine 200. There are ten major procedures of shape embedding engine shown in FIG. 15: registration point derivation and reduction 710, registration points weighting 720, registration points ranking 730, sampling registration points 740, derivation of transformation matrices 750, special process for indeterminate embedding 760, LHS candidates generating 770, embedding checking 780, RHS candidates generating 790, and equivalency reduction 795.

The first procedure of the shape embedding engine 700 derives the intersection of maximal lines for both LHS shape u and the design W. Note that the intersections between those maximal lines with different attributes are derived as well, furthermore, the attributes of lines are attached to the registration point. If multiple intersections coincide at the same point, they are reduced 710 into one registration point and the attributes of the removed registration points are attached to the one left. The second procedure 720 calculates the weight for each registration point for both LHS shape u and the design W. The weights of registration points help the engine to rank 730 and sample 740 the registration points from u and W so that the search body can be reduced. The third procedure 750 derives the transformation matrices from the sampled registration points.

The fourth procedure 770 generates all the candidates f(u) with the derived transformations fs. The fifth procedure 780 checks all candidates if they can be embedded into W and excludes those transformations that cannot make shape u embedded in W. The next procedures use the set of transformations f′ that can make the shape u embedded in W to generate 790 all the corresponding candidates of the right-hand-side shape f′(v). The final procedure 795 eliminates all the identical copies, both for the left-hand-side shapes and the right-hand-side shapes, to keep the results nonequivalent. For the indeterminate embedding 760, the engine 700 determines the embedding case in the beginning of the process by simply checking the number of registration points of shape u and the transformation parameters. If the embedding is indeterminate, a special process will be activated to calculate the ranges of required parameters ([17]) and send the ranges to the communication/control layer to compile a message and echo it back to users to ask for further parameters. After receiving the parameters, the engine 700 continues the embedding process with parameters.

Rule Application Unit 800

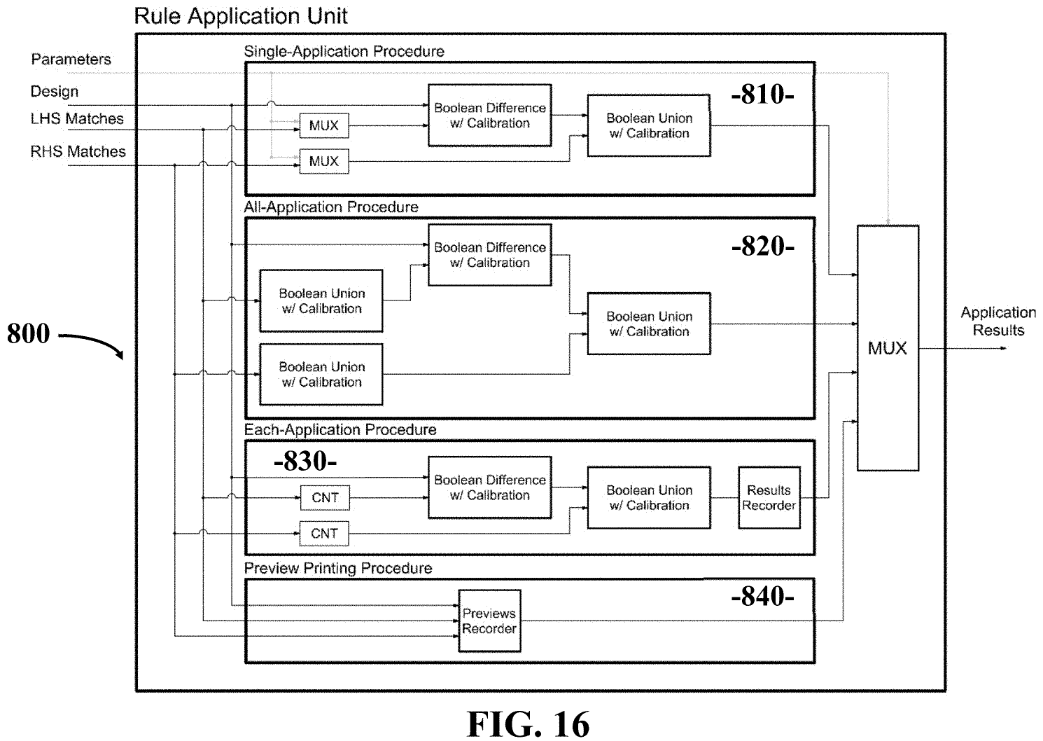

There are four major procedures of rule application unit 800 shown in FIG. 16: single-application process 810, all-applications process 820, each-application process 830, and all-preview printing process 840.

After the shape embedding engine 700, all the matches, fₙ(u) and fₙ(v) will be sent to communication/control layer 300 to generate the preview and the control parameters for users. Preview of rule application is real-timely generated and shown on the design in a random order. Users can input different parameters to control the system, for example, the system will show the preview of the next match if users press enter/return key; the current match will be applied if users input ‘1’; all matches will be applied in parallel if users input ‘2’; the matches are processed one by one and all the results are recorded if users input ‘3’; all the preview will be printed if users input ‘4’; the system exits without any change if users press ‘0’. The parameter is sent to rule application unit 800 and active the corresponding procedure to finish the process. Each procedure basically is implemented with multiple Boolean union units and Boolean difference units in addition to a control system. Each Boolean operation unit is implemented with a calibration mechanism.

Maximal Line Calibration

Calibration for maximal lines is a mechanism proposed to reduce the accumulated error caused by the floating-point arithmetic of CAD geometry. Checking parallelism and collinearity between two lines is a required pre-process for line maximization ([5]). Checking for parallelism and collinearity in well-defined cases of lines, for example, rectilinear shapes or otherwise shapes whose endpoints snap upon a grid system, appears straightforward, but even then, the import of transformations brings problems in such comparisons (Krishnamurti and Stouffs, 1997), and the extension of such calculations and procedures for all lines, rational and irrational ones, brings even more precision errors and renders these computations idle. For instance, the slight precision errors between two parallel lines make them, in reality, non-parallel as they will in fact, intersect eventually in a point. The usage of floating-point numbers to represent real numbers, does not solve the problem as it is only an approximation and this issue is still inevitable. Most detrimentally, it is almost virtually impossible to discern with a naked eye such precision errors as the lines do appear parallel to one another. From a user's perspective, the system should recognize these two lines as a pair of parallel lines.

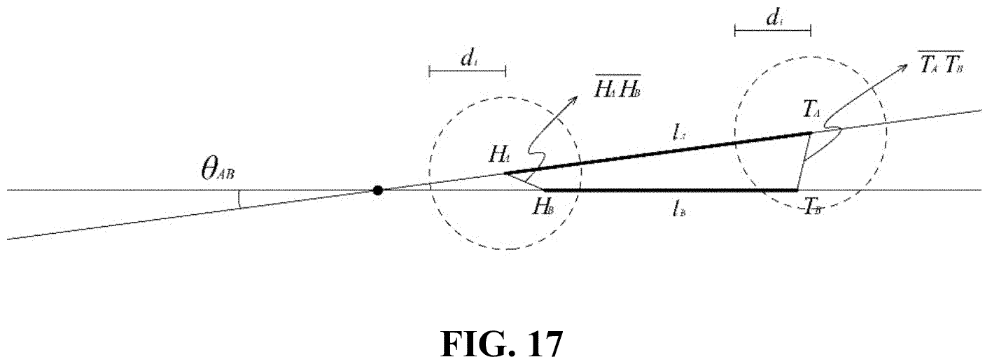

Therefore, setting up a tolerance helps reduce the effects caused by precision errors. FIG. 17 shows an example that two lines are recognized as equal because the distance between two endpoints H_{A} and H_{B} is smaller than the tolerance dₜ and the distance between the endpoints T_{A} and T_{B} is smaller than the tolerance dₜ too. The two lines, l_{A} and l_{B}, are almost parallel with an angle θ_{AB}, at the same time, their endpoints are very close to each other. In this case, the system should recognize these two lines are equal because the distance between the endpoints H_{A} and H_{B} is smaller than the tolerance dₜ; and, the distance between the endpoints T_{A} and T_{B} is smaller than the tolerance dₜ too. The condition to examine if two lines are equal can be described as: H̅_̅{̅A̅}̅H̅_̅{̅B̅}̅≤dₜ and T̅_̅{̅A̅}̅T̅_̅{̅B̅}̅≤dₜ, or, T̅_̅{̅A̅}̅H̅_̅{̅B̅}̅≤dₜ and H̅_̅{̅A̅}̅T̅_̅{̅B̅}̅≤dₜ.

This examination method is generalized for all the possible relations between two lines by examining the following features:

1) The angle θ_{AB} between the two hyperplanes h_{A} and h_{B} where l_{A} and l_{B} are embedded;

2) the distances H̅_̅{̅A̅}̅H̅_̅{̅B̅}̅ between the endpoint H_{A} and the endpoint H_{B};

3) the distance T̅_̅{̅A̅}̅T̅_̅{̅B̅}̅ between the endpoint T_{A} and the endpoint T_{B};

4) the distance T̅_̅{̅A̅}̅H̅_̅{̅B̅}̅ between the endpoint T_{A} and the endpoint H_{B};

5) the distance H̅_̅{̅A̅}̅T̅_̅{̅B̅}̅ between the endpoint H_{A} and the endpoint T_{B};

6) the angle θ_{H}_{_{A}} between the vectors [symbol] and [symbol] ;

7) the angle θ_{T}_{_{A}} between the vectors [symbol] and [symbol] ;

8) the angle θ_{H}_{_{B}} between the vectors [symbol] and [symbol] ; and

9) the angle θ_{T}_{_{B}} between the vectors [symbol] and [symbol] .

The system labels the relationships between two line with the following conditions:

1. Two lines are parallel and they are not collinear if:
a. (−θₜ≤θ_{AB}≤θₜ or π−θₜ≤θ_{AB}≤π+θₜ) and
b. ((−π+θₜ<θ_{H}_{_{A}}<−θₜ or θₜ<θ_{H}_{_{A}}<π<θₜ) and (−π+θₜ<θ_{T}_{_{A}}<−θₜ or θₜ<θ_{T}_{_{A}}<π−θₜ)) and
c. ((−π+θₜ<θ_{H}_{_{B}}<−θₜ or θₜ<θ_{H}_{_{B}}<π−θₜ) and (−π+θₜ<θ_{T}_{_{B}}<−θₜ or θₜ<θ_{T}_{_{B}}<π−θₜ))

2. Two lines are collinear and the intersection of lₐ and l_{B} is empty shape if:
a. (H̅_̅{̅A̅}̅H̅_̅{̅B̅}̅>dₜ and T̅_̅{̅A̅}̅T̅_̅{̅B̅}̅>dₜ and H̅_̅{̅A̅}̅T̅_̅{̅B̅}̅>dₜ and T̅_̅{̅A̅}̅H̅_̅{̅B̅}̅>dₜ) and
b. ((−θₜ≤θ_{H}_{_{A}}≤θₜ) and (−θₜ≤θ_{T}_{_{A}}≤θₜ)) and
c. ((−θₜ≤θ_{H}_{_{B}}≤θₜ) and (−θₜ≤θ_{T}_{_{B}}≤θₜ))

3. Two lines are collinear and one endpoint of l_{A} coincides with one endpoint of l_{B}, and l_{B} is not embedded in l_{A}, and l_{A} is not embedded in l_{B} if:
a. ((̅H̅_̅{̅A̅}̅H̅_̅{̅B̅}̅≤dₜ and T̅_̅{̅A̅}̅T̅_̅{̅B̅}̅>dₜ) and (−θₜ≤θ_{T}_{_{A}}≤θₜ) and (−θₜ≤θ_{T}_{_{B}}≤θₜ)) or
b. ((T̅_̅{̅A̅}̅T̅_̅{̅B̅}̅≤dₜ and H̅_̅{̅A̅}̅H̅_̅{̅B̅}̅>dₜ) and (−θₜ≤θ_{H}_{_{A}}≤θₜ) and (−θₜ≤θ_{H}_{_{B}}≤θₜ)) or
c. ((H̅_̅{̅A̅}̅T̅_̅{̅B̅}̅≤dₜ and T̅_̅{̅A̅}̅H̅_̅{̅B̅}̅>dₜ) and (−θₜ≤θ_{T}_{_{A}}≤θₜ) and (−θₜ≤θ_{H}_{_{B}}≤θₜ)) or
d. ((T̅_̅{̅A̅}̅H̅_̅{̅B̅}̅≤dₜ and H̅_̅{̅A̅}̅T̅_̅{̅B̅}̅>dₜ) and (−θₜ≤θ_{H}_{_{A}}≤θₜ) and (−θₜ≤θ_{T}_{_{B}}≤θₜ))

4. Two lines are collinear and only one endpoint of l_{B} occurs between two endpoints of l_{A} if:
a. (H̅_̅{̅A̅}̅H̅_̅{̅B̅}̅>dₜ and T̅_̅{̅A̅}̅T̅_̅{̅B̅}̅>dₜ and H̅_̅{̅A̅}̅T̅_̅{̅B̅}̅>dₜ and T_{A}H_{B}>dₜ) and
   i. ((−θₜ≤θ_{H}_{_{A}}≤θₜ) and (π−θₜ≤θ_{T}_{_{A}}≤π+θₜ) and (π−θₜ≤θ_{H}_{_{B}}≤π+θₜ) and (−θₜ≤θ_{T}_{_{B}}≤θₜ)) or
   ii. ((−θₜ≤θ_{H}_{_{A}}≤θₜ) and (π−θₜ≤θ_{T}_{_{A}}≤π−+θₜ) and (−θₜ≤θ_{H}_{_{B}}≤θₜ) and (π−θₜ≤θ_{T}_{_{B}}≤π+θₜ)) or
   iii. ((π−θₜ≤θ_{H}_{_{A}}≤π+θₜ) and (−θₜ≤θ_{T}_{_{A}}≤θₜ) and (π−θₜ≤θ_{H}_{_{B}}≤π+θₜ) and (−θₜ≤θ_{T}_{_{B}}≤θₜ)) or
   iv. ((π−θₜ≤θ_{H}≤π+θₜ) and (−θₜ≤θ_{T}_{_{A}}≤θₜ) and (−θₜ≤θ_{H}_{_{B}}≤θₜ) and (π−θₜ≤θ_{T}_{_{B}}≤π+θₜ))

5. l_{B} is embedded in l_{A} and only one endpoint of l_{B} coincides with one endpoint of l_{A} if:
a. ((H̅_̅{̅A̅}̅H̅_̅{̅B̅}̅≤dₜ and T̅_̅{̅A̅}̅T̅_̅{̅B̅}̅>dₜ) and (−θₜ≤θ_{T}_{_{A}}≤θₜ) and (π−θₜ≤θ_{T}_{_{B}}≤π+θₜ)) or
b. ((T̅_̅{̅A̅}̅T̅_̅{̅B̅}̅≤dₜ and H̅_̅{̅A̅}̅H̅_̅{̅B̅}̅>dₜ) and (−θₜ≤θ_{H}_{_{A}}≤θₜ) and (π−θₜ≤θ_{H}_{_{B}}≤π+θₜ)) or
c. ((H̅_̅{̅A̅}̅T̅_̅{̅B̅}̅≤dₜ and T̅_̅{̅A̅}̅H̅_̅{̅B̅}̅>dₜ) and (−θₜ≤θ_{T}_{_{A}}≤θₜ) and (π−θₜ≤θ_{H}_{_{B}}≤π+θₜ)) or
d. ((≤dₜ and H̅_̅{̅A̅}̅T̅_̅{̅B̅}̅>dₜ) and (−θₜ≤θ_{H}_{_{A}}≤θₜ) and (π−θₜ≤θ_{T}_{_{B}}π+θₜ))

6. Two lines are equal if:
a. (H̅_̅{̅A̅}̅H̅_̅{̅B̅}̅≤dₜ and T̅_̅{̅A̅}̅T̅_̅{̅B̅}̅≤dₜ) or
b. (T̅_̅{̅A̅}̅H̅_̅{̅B̅}̅≤dₜ and H̅_̅{̅A̅}̅T̅_̅{̅B̅}̅≤dₜ)

7. l_{B} is embedded in l_{A} and no endpoint of l_{B} coincides any endpoint of l_{A} if:
a. (H̅_̅{̅A̅}̅H̅_̅{̅B̅}̅>dₜ and T̅_̅{̅A̅}̅T̅_̅{̅B̅}̅>dₜ and H̅_̅{̅A̅}̅T̅_̅{̅B̅}̅>dₜ and T̅_̅{̅A̅}̅H̅_̅{̅B̅}̅>dₜ) and
b. ((−θₜ≤θ_{H}_{_{A}}≤θₜ) and (−θₜ≤θ_{T}_{_{A}}≤θₜ)) and
c. ((π−θₜθ_{H}_{_{B}}π+θₜ) and (π−θₜ≤θ_{T}_{_{B}}≤π+θₜ))

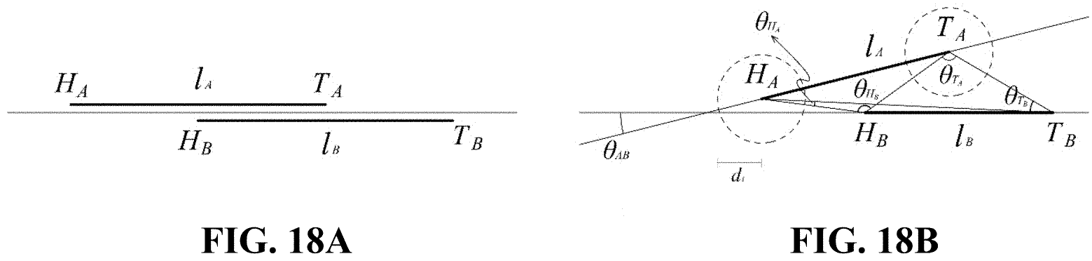

For each pair of lines, the system examines the nine features to determine the relation between this pair of line. Among these seven parallel cases, a Boolean union operation will be processed on cases 3, 4, 5 and 6 to obtain the maximal line representation. FIGS. 18A-18B show an example of two collinear lines without precision error and an example of the imperfect collinear lines, where two lines are collinear and only one endpoint of l_{B} occurs between two endpoints of l_{A}. FIG. 18A: l_{A} and l_{B} are in this case of relation without any precision error; FIG. 18B: an imperfect instance of this case of relation where l_{A} and l_{B} are neither truly parallel nor truly collinear.

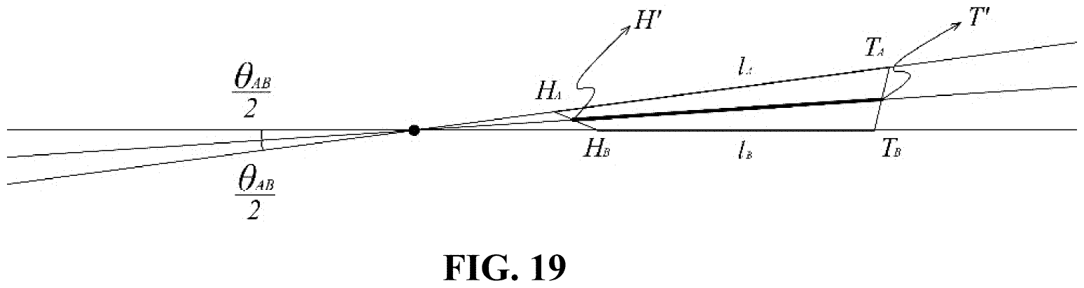

Maximization of lines in the shape machine 200 is also processed with the tolerance, a new maximal line will be redrafted for every maximization process. For instance, the pair of lines in FIG. 17 are recognized as two equal lines so that the maximization will be processed. Both l_{A} and l_{B} are removed and a new line l′ with new endpoints H′ and T′ is created and embedded in a new hyperplane h′. The new hyperplane h′ is the bisector of the hyperplane h_{A} and h_{B}. H′ is the intersection of h′ and H_{A}H_{B}; T′ is the intersection of h′ and T_{A}T_{B} shown in FIG. 19.

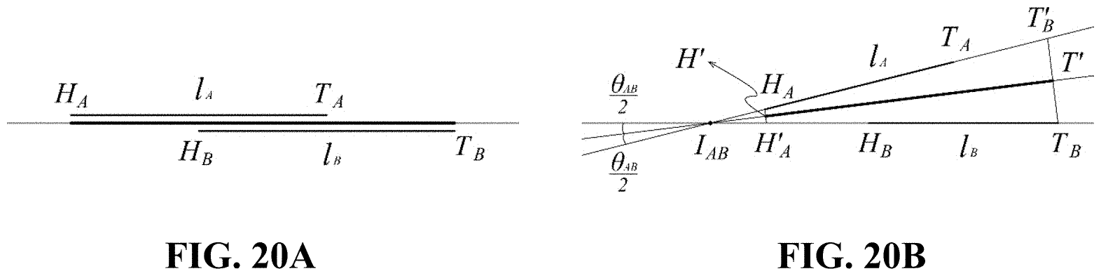

The maximization is processed according to different cases of relations. For the example in FIGS. 18A-18B, the ideal case is to remove the endpoints T_{A} and H_{B}, then create a new maximal line with the endpoints H_{A} and T_{B}. In the case with precision errors, a bisector of h_{A} and h_{B} is created as the new hyperplane, and the system marks out two temporary points H′_{A} and T′_{A} on h_{B} and h_{A} respectively, that H̅′̅_̅{̅A̅}̅I̅_̅{̅A̅B̅}̅=H̅_̅{̅A̅}̅I̅_̅{̅A̅B̅}̅ and T̅_̅{̅B̅}̅I̅_̅{̅A̅B̅}̅=T̅_̅{̅B̅}̅I̅_̅{̅A̅B̅}̅. The new maximal line is created with the endpoints H′ and T′ where H′ is the point of intersection of new hyperplane h′ and the line H_{A}H′_{A}; T′ is the point of intersection of new hyperplane h′ and T_{B}T′_{B}. FIGS. 20A-20B are an example of the maximization for two lines with line relationship where two lines are collinear and only one endpoint of l_{B} occurs between two endpoints of l_{A}. FIG. 20A: An example of maximization without any precision error where l_{A} and l_{B} are both removed and a new maximal line with endpoints H_{A} and T_{B} is created; FIG. 20B: An example of maximization with precision errors where l_{A} and l_{B} are both removed and a new maximal line with endpoints H′ and T′ is created.

In general, the endpoint, which is supposed to be kept if there is no precision error, will be calibrated by projecting it onto the new hyperplane which is the bisector of the hyperplanes where lines are embedded. This mechanism provides the tolerances of angle and distance so that not only rectilinear shapes are supported but also no need to snap shapes onto a grid system. Furthermore, this mechanism is also applied to the shape Boolean operations including Boolean union and Boolean subtraction with the same logic that the kept endpoints are projected to the new hyperplane. FIGS. 21A-21B show an example of the calibration in Boolean difference l_{A}−l_{B} where l_{B} is embedded in l_{A} and none of the endpoints of l_{B} coincides with any endpoint of l_{A}. FIG. 21A: An example of Boolean difference without any precision error where l_{A} and l_{B} are both removed and two new maximal lines 11 with endpoints H_{A} and H_{B} and l′₂ with endpoints T_{B} and T_{A}, are created; FIG. 21B: An example of Boolean difference with precision errors where l_{A} and l_{B} are both removed and two new maximal lines l′₁ with new endpoints H′₁, T′₁ and l′₂ with new endpoints H′₂, T′₂ are created.

Pictorial Derivation of Shape Embedding Transformations

The implementation of pictorial derivation of transformations is proposed to address the problems with calculations plaguing the derivation of transformation matrices especially for affine, and mostly, perspectival transformations under which a shape rule can apply. Here, the transformation that can embed a shape u in a shape W is derived by a series of geometric procedures involving a minimum of numerical calculations. These algorithms are processed by geometrically reconstructing a congruent, similar, affine congruent, and projective congruent shape u on the shape W with the selected registration points and their hyperplanes as the references for the mapping. The pictorial approaches are applicable for the derivations of isometries, similarities, affinities and perspectivities respectively.

Note that the pictorial approach is not able to reduce the number of the sampling registration points, that is, the sampling body is the same as the one using transformation matrices. Also, note that the pictorial approach aims for precision in calculation, instead of performance (speed), thusly it typically causes more computation time since the geometric construction requires multiple steps processed in a recursive manner. Briefly, the pictorial approach is adopted as the alternative of calculation to mitigate the accumulated errors caused by the derivations of transformations through high-degree calculations. The rest of the process including registration point sampling, reduction of the equivalent copies and Boolean operations remains the same. the present invention is equipped with both modes of derivation of transformations, and will switch to the modes back and forth according to different conditions.

The implementation of the pictorial approach in the present invention requires the simulation of six geometric operations by corresponding numerical calculations:

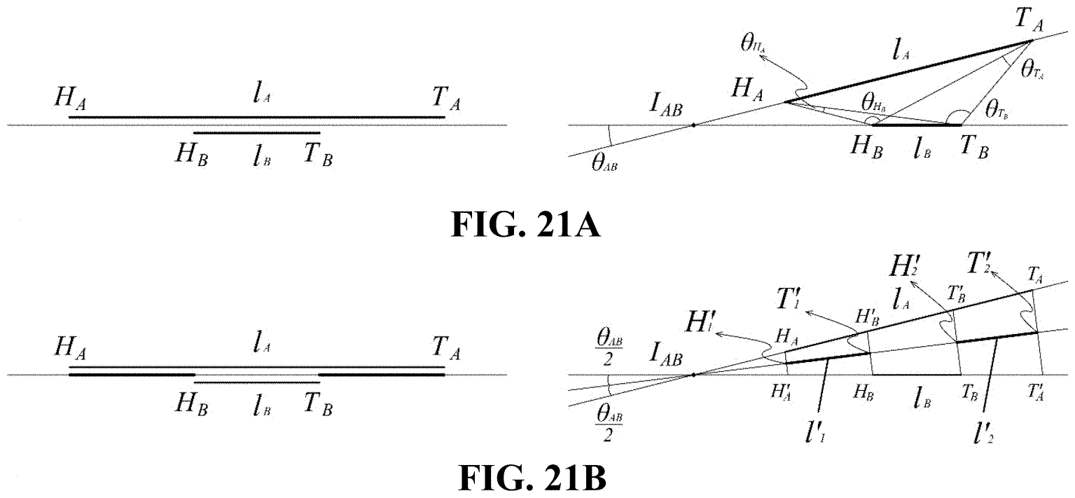

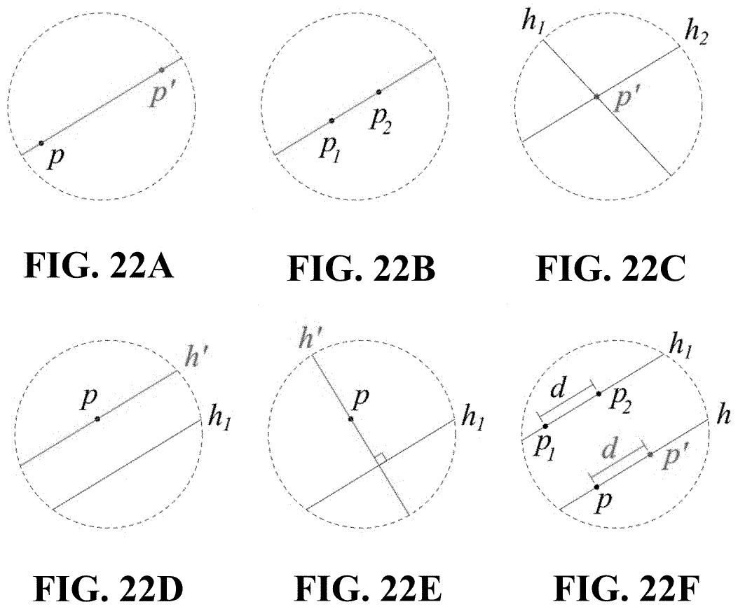

1) Constructing an arbitrary hyperplane through a given point (see FIG. 22A): The construction is simulated by assigning a line equation ax+by +c=0 in the database with the coefficient (a, b, c) where a and b are random floating-point numbers and c is derived with the given coordinates (x, y).

2) Constructing a hyperplane with two given points (see FIG. 22B): The construction is simulated by deriving the line equations ax+by +c=0 from the two points (x₁, yᵢ) and (x₂, y₂), and assign the hyperplane to database with the derived coefficients (a, b, c).

3) Finding a point of intersection of two given non-parallel hyperplanes (see FIG. 22C): The construction is simulated by deriving the solution (x, y) of two line equations a₁x+b₁y+c₁=0 and a₂x+b₂y+c₂=0. After derivation of the solution, a point of intersection is assigned to the database as (x, y).

4) Constructing a hyperplane ax+by +c′=0 which is parallel to a given hyperplane ax+by +c=0 through a given point (x, y) which does not lie on the given hyperplane (see FIG. 22D): The construction is simulated by deriving the coefficient c′, and assigning the derived hyperplane with the coefficients (a, b, c′) to database.

5) Constructing a hyperplane bx−ay+c′=0 which is perpendicular to a given hyperplane ax+by +c=0 through a given point (x, y) (see FIG. 22E): The construction is simulated by deriving the coefficient c′, and assigning the derived hyperplane with the coefficients (b, −a, c′) to database.

6) Given two points p₁ and p₂, constructing a point p′ on a given hyperplane h′ with a given point p on h′ and let p̅′̅p̅=p̅₁̅p̅₂̅ (see FIG. 22F): The construction is simulated by: a) deriving a distance d with the two given points, b) deriving a normalized vector \vec{v} from the line equation and c) instantiating a point by adding the scaled vector d\vec{v} on the given point p.

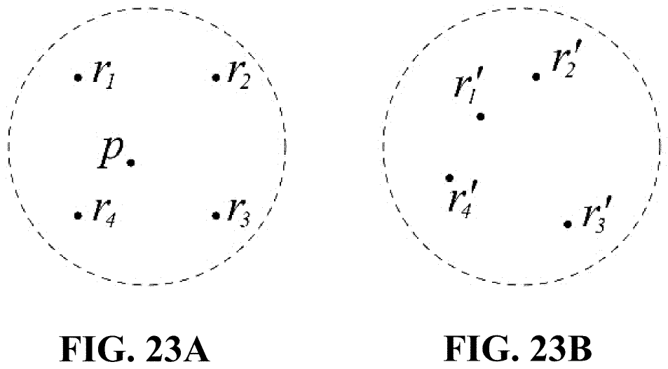

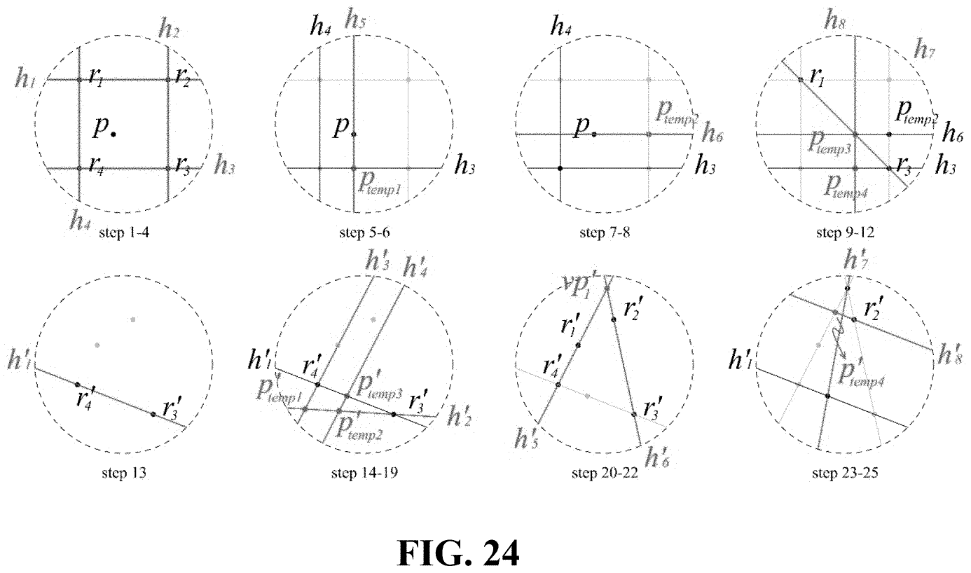

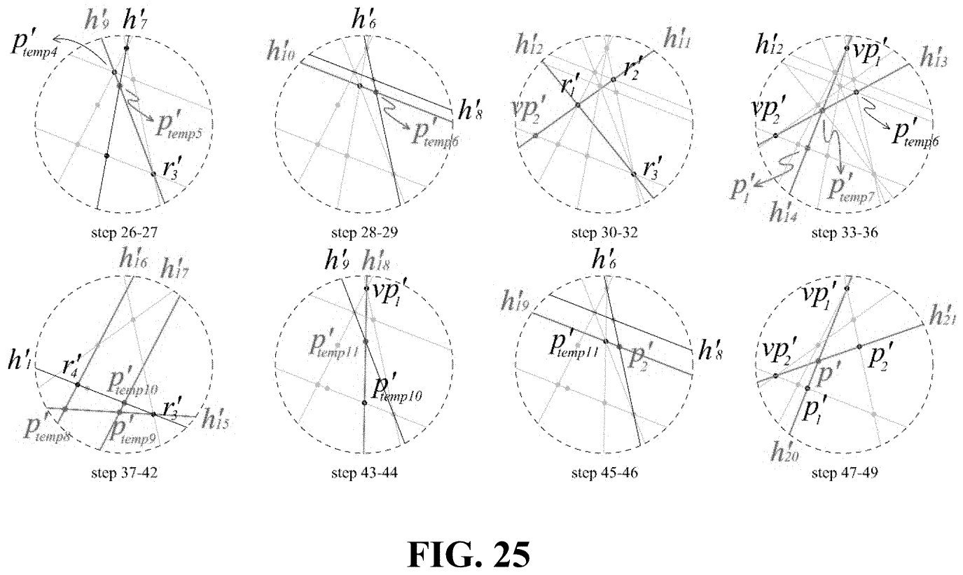

An example of a pictorial derivation of a linear transformation through the construction of a projective congruent spatial relation is given below. To derive the transformed point p′ under a linear transformation, that is, a combinations of a one-point perspective transformation or a two-point perspective transformation with a translation, rotation, reflection, scaling, stretching and shearing, the geometrical construction requires four registration points to determine the transformation. The construction involves all six basic geometric operations. The pictorial approach to map the four registration points r₁, r₂, r₃ and r₄ in FIG. 23A to the four given registration points r′₁, r′₂, r′₃ and r′₄ as the targeted references in FIG. 23B requires 49 steeps illustrated at the FIGS. 24-26.

The four registration points can be ordered in eight ways, that is, (r₁, r₂, r₃, r₄), (r₄, r₁ r₂, r₃), (r₃, r₄, r₁, r₂), (r₂, r₃, r₄, r₁), (r₄, r₃, r₂, r₁), (r₁, r₄, r₃, r₂), (r₂, r₁, r₄, r₃) and (r₃, r₂, r₁, r₄). Note that the order of the registration points is cyclic version of (r₁, r₂, r₃, r₄) and (r₄, r₃, r₂, r₁), hence the orders such as (r₁, r₃, r₂, r₄) and (r₁, r₄, r₂, r₃) are invalid. The targeted registration points can be ordered in eight ways as well, that is (r′₁, r′₂, r′₃, r′₄), (r′₄, r′₁ r′₂, r′₃), (r′₃, r′₄, r′₁, r′₂), (r′₂, r′₃, r′₄, r′₁), (r′₄, r′₃, r′₂, r′₁), (r′₁, r′₄, r′₃, r′₂), (r′₂, r′₁, r′₄, r′₃) and (r′₃, r′₂, r′₁, r′₄) Therefore, there 8×8=64 possible results including all the congruent copies.

The steps 1 to 4 are to construct four hyperplanes h₁ with r₁ and r₂, h₂ with r₂ and r₃, h₃ with r₃ and r₄ and h₄ with r₄ and r₁ by applying the geometric operation 2 for four times. The step 5 and step 6 are to construct a hyperplane h₅ which is parallel to h₂ through the point p by applying the geometric operation 4, and find the point of intersection Nₜₑₘₚ₁ of the hyperplane h₃ and h₅ by applying the geometric operation 3. The step 7 and step 8 are to construct a hyperplane h₆ which is parallel to h₃ through the point p by applying the geometric operation 4, and find the point of intersection pₜₑₘₚ₂ of the hyperplane h₄ and h₆ by applying the geometric operation 3. The steps 9 to 12 are to construct a hyperplane h₇ with r₂ and r₄ by applying the geometric operation 2; find the point of intersection pₜₑₘₚ₃ of hyperplanes h₆ and h₈ by applying the geometric operation 3; construct a hyperplane h₈ which is parallel to h₄ through the point pₜₑₘₚ₃ by applying the geometric operation 4; and find the point of intersection pₜₑₘₚ₄ of hyperplanes h₃ and h₈ by applying the geometric operation 3. The step 13 is to construct a hyperplane r′₁ with r′₃ and r′₄ by applying the geometric operation 2. The steps 14 to 19 are to construct an arbitrary hyperplane h′₂ through r′₃ and let h′₃ is not collinear with h′₁ by applying the geometric operation 1; construct a point p′ₜₑₘₚ₁ on the hyperplane h′₂ and let r̅′̅₃̅p̅′̅ₜ̅ₑ̅ₘ̅ₚ̅₁̅=r̅₃̅r̅₄̅ by applying the geometric operation 6; construct a point p′ₜₑₘₚ₂ on the hyperplane h′₂ and let r̅′̅₃̅p̅′̅ₜ̅ₑ̅ₘ̅ₚ̅₂̅=r̅₃̅p̅ₜ̅ₑ̅ₘ̅ₚ̅₁̅ by applying the geometric operation 6; construct a hyperplane h′₃ with p′ₜₑₘₚ₁ and r′₄ by applying the geometric operation 2; construct a hyperplane h′₄ which is parallel to h′₃ through the point p′ₜₑₘₚ₂ by applying the geometric operation 4; and find the point of intersection pₜₑₘₚ₃ of hyperplanes h′₁ and h′₄ by applying the geometric operation 3. The steps 20 to 22 are to construct hyperplane h′₅ with r′₁ and r′₄ by applying the geometric operation 2; construct hyperplane h′₆ with r′₂ and r′₃ by applying the geometric operation 2; and find the point of intersection vp′₁ by applying the geometric operation 3. The steps 23 to 25 are to construct a hyperplane h′₇ with vp′₁ and p′ₜₑₘₚ₃ by applying the geometric operation 2; construct a hyperplane h′₈ which is parallel to h′₁ through r′₂; and find the intersection p′ₜₑₘₚ₄ by applying the geometric operation 3.

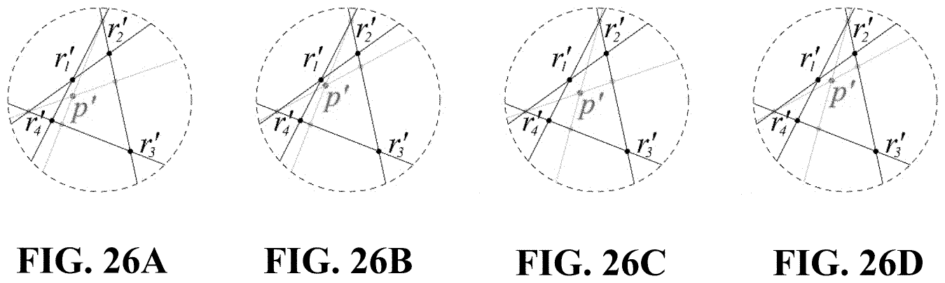

The steps 26 and 27 are to construct a hyperplane h′₉ with r′₃ and p′ₜₑₘₚ₄ by applying the geometric operation 2; and find the point of intersection p′ₜₑₘₚ₅ of hyperplanes h′₇ and h′₉, by applying the geometric operation 3. The steps 28 and 29 are to construct a hyperplane h′₁₀ which is parallel to h′₈ through the point p′ₜₑₘₚ₅ by applying the geometric operation 4; and find the point of intersection p′ₜₑₘₚ₆ of hyperplanes h′₆ and h′₁₀ by applying the geometric operation 3. The steps 30 to 32 are to construct a hyperplane h′₁₁ with r′₁ and r′₂ by applying the geometric operation 2; find the point of intersection vp′₂ of hyperplanes h′₁ and h′₁₁ by applying the geometric operation 3; and construct a hyperplane h′₁₂ with r′₁ and r′₃ by applying the geometric operation 2. The steps 33 to 36 are to construct a hyperplane h′₁₃ with vp′₂ and p′ₜₑₘₚ₆ by applying the geometric operation 2; find the point of intersection p′ₜₑₘₚ₇ of hyperplanes h′₁₂ and h′₁₃ by applying the geometric operation 3; construct a hyperplane h′₁₄ with vp′₁ and p′ₜₑₘₚ₇ by applying the geometric operation 2; and find the point of intersection p′₁ of hyperplanes h′₁ and h′₁₄ by applying the geometric operation 3. The steps 37 to 42 are to construct an arbitrary hyperplane h′₁₅ through r′₃ and let h′₁₅ is not collinear with h′₁ by applying the geometric operation 1; construct a point p′ₜₑₘₚ₈ on the hyperplane h′₁₅ and let r̅′̅₃̅p̅′̅ₜ̅ₑ̅ₘ̅ₚ̅₈̅=r̅₃̅r̅₄̅ by applying the geometric operation 6; construct a point p′ₜₑₘₚ₉ on the hyperplane h′₁₅ and let r̅′̅₃̅p̅′̅ₜ̅ₑ̅ₘ̅ₚ̅₉̅=r̅₃̅p̅ₜ̅ₑ̅ₘ̅ₚ̅₄̅ by applying the geometric operation 6; construct a hyperplane h′₁₆ with p′ₜₑₘₚ₈ and r′₄ by applying the geometric operation 2; construct a hyperplane h′₁₇ which is parallel to h′₁₆ through the point p′ₜₑₘₚ₉ by applying the geometric operation 4; and find the point of intersection p′ₜₑₘₚ₁₀ of hyperplanes h′₁ and h′₁₇ by applying the geometric operation 3. The steps 43 and 44 are to construct a hyperplane h′₁₈ with vp′₁ and p′ₜₑₘₚ₁₀ by applying the geometric operation 2; and find the point of intersection p′ₜₑₘₚ₁₁ of hyperplanes h′₉ and h′₁₈ by applying the geometric operation 3. The steps 45 and 46 are to construct a hyperplane h′₁₉ which is parallel to through the point p′ₜₑₘₚ₁₁ by applying the geometric operation 4; and find the point of intersection p′₂ of hyperplanes h′₆ and h′₁₉ by applying the geometric operation 3. The steps 47 to 49 are to construct a hyperplane h′₂₀ with vp′₁ and p′₁ by applying the geometric operation 2; construct a hyperplane h′₂₁ with vp′₂ and p′₂ by applying the geometric operation 2; and find the point of intersection p′ of hyperplanes h′₂₀ and h′₂₁ by applying the geometric operation 3. Finally, the point p′ is the congruent copy of the point p under linear transformation. Note that there are 64 ways to construct the point, however, 60 of them can be reduced because are equivalent copies, therefore there are four inequivalent results (see FIGS. 26A-26D) and they are congruent copies of the point p under linear transformation.

These alternatives are caused by the symmetry of the spatial relation between the point p and the references (registration points r₁, r₂, r₃ and r₄). Here, the symmetry n of the spatial relation between the four points is captured by the symmetry of the group D₄, a dihedral group of order 8 and any of its subgroups equal to 8, 4, 2 and 1. The symmetric relation of the point to the arrangement of the four points—the point lies on one of the diagonals of the arrangement, a reflection for the D₄ group and a symmetry element of order 2—and the total number of possible constructions is

$$\frac{n}{q} = \frac{8}{2} = 4 .$$

The pictorial approach derives all the transformations f₁, f₂, f₃ and f₄. The first result of the congruent copy of p (see FIG. 26A) is the equivalent result for the pairs of the sampled registration points in the orders that are

$$( \begin{matrix}{r}_{1} , {r}_{2} , {r}_{3} , {r}_{4} \\ {r}_{1}^{′} , {r}_{2}^{′} , {r}_{3}^{′} , {r}_{4}^{′}\end{matrix} ) , ( \begin{matrix}{r}_{4} , {r}_{1} , {r}_{2} , {r}_{3} \\ {r}_{4}^{′} , {r}_{1}^{′} , {r}_{2}^{′} , {r}_{3}^{′}\end{matrix} ) , ( \begin{matrix}{r}_{3} , {r}_{4} , {r}_{1} , {r}_{2} \\ {r}_{3}^{′} , {r}_{4}^{′} , {r}_{1}^{′} , {r}_{2}^{′}\end{matrix} ) , \\ ( \begin{matrix}{r}_{2} , {r}_{3} , {r}_{4} , {r}_{1} \\ {r}_{2}^{′} , {r}_{3}^{′} , {r}_{4}^{′} , {r}_{1}^{′}\end{matrix} ) , ( \begin{matrix}{r}_{4} , {r}_{3} , {r}_{2} , {r}_{1} \\ {r}_{4}^{′} , {r}_{3}^{′} , {r}_{2}^{′} , {r}_{1}^{′}\end{matrix} ) , ( \begin{matrix}{r}_{1} , {r}_{4} , {r}_{3} , {r}_{2} \\ {r}_{1}^{′} , {r}_{4}^{′} , {r}_{3}^{′} , {r}_{2}^{′}\end{matrix} ) , \\ ( \begin{matrix}{r}_{2} , {r}_{1} , {r}_{4} , {r}_{3} \\ {r}_{2}^{′} , {r}_{1}^{′} , {r}_{4}^{′} , {r}_{3}^{′}\end{matrix} ) , ( \begin{matrix}{r}_{3} , {r}_{2} , {r}_{1} , {r}_{4} \\ {r}_{3}^{′} , {r}_{2}^{′} , {r}_{1}^{′} , {r}_{4}^{′}\end{matrix} ) , ( \begin{matrix}{r}_{1} , {r}_{2} , {r}_{3} , {r}_{4} \\ {r}_{3}^{′} , {r}_{2}^{′} , {r}_{1}^{′} , {r}_{4}^{′}\end{matrix} ) , \\ ( \begin{matrix}{r}_{4} , {r}_{1} , {r}_{2} , {r}_{3} \\ {r}_{4}^{′} , {r}_{3}^{′} , {r}_{2}^{′} , {r}_{1}^{′}\end{matrix} ) , ( \begin{matrix}{r}_{3} , {r}_{4} , {r}_{1} , {r}_{2} \\ {r}_{1}^{′} , {r}_{4}^{′} , {r}_{3}^{′} , {r}_{2}^{′}\end{matrix} ) , ( \begin{matrix}{r}_{2} , {r}_{3} , {r}_{4} , {r}_{1} \\ {r}_{2}^{′} , {r}_{1}^{′} , {r}_{4}^{′} , {r}_{3}^{′}\end{matrix} ) , \\ ( \begin{matrix}{r}_{4} , {r}_{3} , {r}_{2} , {r}_{1} \\ {r}_{4}^{′} , {r}_{1}^{′} , {r}_{2}^{′} , {r}_{3}^{′}\end{matrix} ) , ( \begin{matrix}{r}_{1} , {r}_{4} , {r}_{3} , {r}_{2} \\ {r}_{3}^{′} , {r}_{4}^{′} , {r}_{1}^{′} , {r}_{2}^{′}\end{matrix} ) , ( \begin{matrix}{r}_{2} , {r}_{1} , {r}_{4} , {r}_{3} \\ {r}_{2}^{′} , {r}_{3}^{′} , {r}_{4}^{′} , {r}_{1}^{′}\end{matrix} ) and \\ ( \begin{matrix}{r}_{3} , {r}_{2} , {r}_{1} , {r}_{4} \\ {r}_{1}^{′} , {r}_{2}^{′} , {r}_{3}^{′} , {r}_{4}^{′}\end{matrix} ) .$$

The second result of the congruent copy of p (see FIG. 26B) is the equivalent result for the pairs of the sampled registration points in the orders that

$$( \begin{matrix}{r}_{1} , {r}_{2} , {r}_{3} , {r}_{4} \\ {r}_{4}^{′} , {r}_{1}^{′} , {r}_{2}^{′} , {r}_{3}^{′}\end{matrix} ) , ( \begin{matrix}{r}_{4} , {r}_{1} , {r}_{2} , {r}_{3} \\ {r}_{3}^{′} , {r}_{4}^{′} , {r}_{1}^{′} , {r}_{2}^{′}\end{matrix} ) , ( \begin{matrix}{r}_{3} , {r}_{4} , {r}_{1} , {r}_{2} \\ {r}_{2}^{′} , {r}_{3}^{′} , {r}_{4}^{′} , {r}_{1}^{′}\end{matrix} ) , \\ ( \begin{matrix}{r}_{2} , {r}_{3} , {r}_{4} , {r}_{1} \\ {r}_{1}^{′} , {r}_{2}^{′} , {r}_{3}^{′} , {r}_{4}^{′}\end{matrix} ) , ( \begin{matrix}{r}_{4} , {r}_{3} , {r}_{2} , {r}_{1} \\ {r}_{3}^{′} , {r}_{2}^{′} , {r}_{1}^{′} , {r}_{4}^{′}\end{matrix} ) , ( \begin{matrix}{r}_{1} , {r}_{4} , {r}_{3} , {r}_{2} \\ {r}_{4}^{′} , {r}_{3}^{′} , {r}_{2}^{′} , {r}_{1}^{′}\end{matrix} ) , \\ ( \begin{matrix}{r}_{2} , {r}_{1} , {r}_{4} , {r}_{3} \\ {r}_{1}^{′} , {r}_{4}^{′} , {r}_{3}^{′} , {r}_{2}^{′}\end{matrix} ) , ( \begin{matrix}{r}_{3} , {r}_{2} , {r}_{1} , {r}_{4} \\ {r}_{2}^{′} , {r}_{1}^{′} , {r}_{4}^{′} , {r}_{3}^{′}\end{matrix} ) , ( \begin{matrix}{r}_{1} , {r}_{2} , {r}_{3} , {r}_{4} \\ {r}_{4}^{′} , {r}_{3}^{′} , {r}_{2}^{′} , {r}_{1}^{′}\end{matrix} ) , \\ ( \begin{matrix}{r}_{4} , {r}_{1} , {r}_{2} , {r}_{3} \\ {r}_{1}^{′} , {r}_{4}^{′} , {r}_{3}^{′} , {r}_{2}^{′}\end{matrix} ) , ( \begin{matrix}{r}_{3} , {r}_{4} , {r}_{1} , {r}_{2} \\ {r}_{2}^{′} , {r}_{1}^{′} , {r}_{4}^{′} , {r}_{3}^{′}\end{matrix} ) , ( \begin{matrix}{r}_{2} , {r}_{3} , {r}_{4} , {r}_{1} \\ {r}_{3}^{′} , {r}_{2}^{′} , {r}_{1}^{′} , {r}_{4}^{′}\end{matrix} ) , \\ ( \begin{matrix}{r}_{4} , {r}_{3} , {r}_{2} , {r}_{1} \\ {r}_{1}^{′} , {r}_{2}^{′} , {r}_{3}^{′} , {r}_{4}^{′}\end{matrix} ) , ( \begin{matrix}{r}_{1} , {r}_{4} , {r}_{3} , {r}_{2} \\ {r}_{4}^{′} , {r}_{1}^{′} , {r}_{2}^{′} , {r}_{3}^{′}\end{matrix} ) , ( \begin{matrix}{r}_{2} , {r}_{1} , {r}_{4} , {r}_{3} \\ {r}_{3}^{′} , {r}_{4}^{′} , {r}_{1}^{′} , {r}_{2}^{′}\end{matrix} ) and ( \begin{matrix}{r}_{3} , {r}_{2} , {r}_{1} , {r}_{4} \\ {r}_{2}^{′} , {r}_{3}^{′} , {r}_{4}^{′} , {r}_{1}^{′}\end{matrix} ) .$$

The third result of the congruent copy of p (see FIG. 26C) is the equivalent result for the pairs of the sampled registration points in the orders that

$$( \begin{matrix}{r}_{1} , {r}_{2} , {r}_{3} , {r}_{4} \\ {r}_{2}^{′} , {r}_{3}^{′} , {r}_{4}^{′} , {r}_{1}^{′}\end{matrix} ) , ( \begin{matrix}{r}_{4} , {r}_{1} , {r}_{2} , {r}_{3} \\ {r}_{1}^{′} , {r}_{2}^{′} , {r}_{3}^{′} , {r}_{4}^{′}\end{matrix} ) , ( \begin{matrix}{r}_{3} , {r}_{4} , {r}_{1} , {r}_{2} \\ {r}_{4}^{′} , {r}_{1}^{′} , {r}_{2}^{′} , {r}_{3}^{′}\end{matrix} ) , \\ ( \begin{matrix}{r}_{2} , {r}_{3} , {r}_{4} , {r}_{1} \\ {r}_{3}^{′} , {r}_{4}^{′} , {r}_{1}^{′} , {r}_{2}^{′}\end{matrix} ) , ( \begin{matrix}{r}_{4} , {r}_{3} , {r}_{2} , {r}_{1} \\ {r}_{1}^{′} , {r}_{4}^{′} , {r}_{3}^{′} , {r}_{2}^{′}\end{matrix} ) , ( \begin{matrix}{r}_{1} , {r}_{4} , {r}_{3} , {r}_{2} \\ {r}_{2}^{′} , {r}_{1}^{′} , {r}_{4}^{′} , {r}_{3}^{′}\end{matrix} ) , \\ ( \begin{matrix}{r}_{2} , {r}_{1} , {r}_{4} , {r}_{3} \\ {r}_{3}^{′} , {r}_{2}^{′} , {r}_{1}^{′} , {r}_{4}^{′}\end{matrix} ) , ( \begin{matrix}{r}_{3} , {r}_{2} , {r}_{1} , {r}_{4} \\ {r}_{4}^{′} , {r}_{3}^{′} , {r}_{2}^{′} , {r}_{1}^{′}\end{matrix} ) , ( \begin{matrix}{r}_{1} , {r}_{2} , {r}_{3} , {r}_{4} \\ {r}_{2}^{′} , {r}_{1}^{′} , {r}_{4}^{′} , {r}_{3}^{′}\end{matrix} ) , \\ ( \begin{matrix}{r}_{4} , {r}_{1} , {r}_{2} , {r}_{3} \\ {r}_{3}^{′} , {r}_{2}^{′} , {r}_{1}^{′} , {r}_{4}^{′}\end{matrix} ) , ( \begin{matrix}{r}_{3} , {r}_{4} , {r}_{1} , {r}_{2} \\ {r}_{4}^{′} , {r}_{3}^{′} , {r}_{2}^{′} , {r}_{1}^{′}\end{matrix} ) , ( \begin{matrix}{r}_{2} , {r}_{3} , {r}_{4} , {r}_{1} \\ {r}_{1}^{′} , {r}_{4}^{′} , {r}_{3}^{′} , {r}_{2}^{′}\end{matrix} ) , \\ ( \begin{matrix}{r}_{4} , {r}_{3} , {r}_{2} , {r}_{1} \\ {r}_{3}^{′} , {r}_{4}^{′} , {r}_{1}^{′} , {r}_{2}^{′}\end{matrix} ) , ( \begin{matrix}{r}_{1} , {r}_{4} , {r}_{3} , {r}_{2} \\ {r}_{2}^{′} , {r}_{3}^{′} , {r}_{4}^{′} , {r}_{1}^{′}\end{matrix} ) , ( \begin{matrix}{r}_{2} , {r}_{1} , {r}_{4} , {r}_{3} \\ {r}_{1}^{′} , {r}_{2}^{′} , {r}_{3}^{′} , {r}_{4}^{′}\end{matrix} ) and \\ ( \begin{matrix}{r}_{3} , {r}_{2} , {r}_{1} , {r}_{4} \\ {r}_{4}^{′} , {r}_{1}^{′} , {r}_{2}^{′} , {r}_{3}^{′}\end{matrix} ) .$$

The fourth result of the congruent copy of p (see FIG. 26D) is the equivalent result for the pairs of the sampled registration points in the orders that

$$( \begin{matrix}{r}_{1} , {r}_{2} , {r}_{3} , {r}_{4} \\ {r}_{3}^{′} , {r}_{4}^{′} , {r}_{1}^{′} , {r}_{2}^{′}\end{matrix} ) , ( \begin{matrix}{r}_{4} , {r}_{1} , {r}_{2} , {r}_{3} \\ {r}_{2}^{′} , {r}_{3}^{′} , {r}_{4}^{′} , {r}_{1}^{′}\end{matrix} ) , ( \begin{matrix}{r}_{3} , {r}_{4} , {r}_{1} , {r}_{2} \\ {r}_{1}^{′} , {r}_{2}^{′} , {r}_{3}^{′} , {r}_{4}^{′}\end{matrix} ) , \\ ( \begin{matrix}{r}_{2} , {r}_{3} , {r}_{4} , {r}_{1} \\ {r}_{4}^{′} , {r}_{1}^{′} , {r}_{2}^{′} , {r}_{3}^{′}\end{matrix} ) , ( \begin{matrix}{r}_{4} , {r}_{3} , {r}_{2} , {r}_{1} \\ {r}_{2}^{′} , {r}_{1}^{′} , {r}_{4}^{′} , {r}_{3}^{′}\end{matrix} ) , ( \begin{matrix}{r}_{1} , {r}_{4} , {r}_{3} , {r}_{2} \\ {r}_{3}^{′} , {r}_{2}^{′} , {r}_{1}^{′} , {r}_{4}^{′}\end{matrix} ) , \\ ( \begin{matrix}{r}_{2} , {r}_{1} , {r}_{4} , {r}_{3} \\ {r}_{4}^{′} , {r}_{3}^{′} , {r}_{2}^{′} , {r}_{1}^{′}\end{matrix} ) , ( \begin{matrix}{r}_{3} , {r}_{2} , {r}_{1} , {r}_{4} \\ {r}_{1}^{′} , {r}_{4}^{′} , {r}_{3}^{′} , {r}_{2}^{′}\end{matrix} ) , ( \begin{matrix}{r}_{1} , {r}_{2} , {r}_{3} , {r}_{4} \\ {r}_{1}^{′} , {r}_{4}^{′} , {r}_{3}^{′} , {r}_{2}^{′}\end{matrix} ) , \\ ( \begin{matrix}{r}_{4} , {r}_{1} , {r}_{2} , {r}_{3} \\ {r}_{2}^{′} , {r}_{1}^{′} , {r}_{4}^{′} , {r}_{3}^{′}\end{matrix} ) , ( \begin{matrix}{r}_{3} , {r}_{4} , {r}_{1} , {r}_{2} \\ {r}_{3}^{′} , {r}_{2}^{′} , {r}_{1}^{′} , {r}_{4}^{′}\end{matrix} ) , ( \begin{matrix}{r}_{2} , {r}_{3} , {r}_{4} , {r}_{1} \\ {r}_{4}^{′} , {r}_{3}^{′} , {r}_{2}^{′} , {r}_{1}^{′}\end{matrix} ) , \\ ( \begin{matrix}{r}_{4} , {r}_{3} , {r}_{2} , {r}_{1} \\ {r}_{2}^{′} , {r}_{3}^{′} , {r}_{4}^{′} , {r}_{1}^{′}\end{matrix} ) , ( \begin{matrix}{r}_{1} , {r}_{4} , {r}_{3} , {r}_{2} \\ {r}_{1}^{′} , {r}_{2}^{′} , {r}_{3}^{′} , {r}_{4}^{′}\end{matrix} ) , ( \begin{matrix}{r}_{2} , {r}_{1} , {r}_{4} , {r}_{3} \\ {r}_{4}^{′} , {r}_{1}^{′} , {r}_{2}^{′} , {r}_{3}^{′}\end{matrix} ) and ( \begin{matrix}{r}_{3} , {r}_{2} , {r}_{1} , {r}_{4} \\ {r}_{3}^{′} , {r}_{4}^{′} , {r}_{1}^{′} , {r}_{2}^{′}\end{matrix} ) .$$

All geometric constructions discussed so far are suggested as alternative algorithms aimed to decomposing (flatten) high-degree calculations into multiple low-degree calculations and avoiding accumulated errors because of the inexact floating-point arithmetic of CAD geometry. The pictorial approach requires multiple iterative steps, and currently the performance is slow. As is, the present invention uses the algebraic approach for the derivation of isometric, similar and affine transformations since the accumulated errors are still in manageable range with the calibration mechanism and switches to pictorial mode for the derivation of linear transformations because the accumulated errors are out of manageable range even with the proposed calibration mechanism. Still, more than the current state of affairs, it is suggested that the two modes of derivation of shape embedding capture two complementary ways of looking at the problem of implementation of shape embedding: The pictorial approach aims for a solution for the derivation of transformations focusing on precision even if the resolution of the CAD systems is low. The symbolic approach aims for a solution for the derivation of transformations focusing on speed if the resolution of the CAD system is high enough to cover the accumulated errors.

Indeterminate Shape Embedding

The implementation of the indeterminate shape embedding for lines is proposed to address the problems that arise when the shape u has less registration points than required to derive the transformation matrices. In general, a shape embedding is indeterminate when the shape u has less registration points than required to derive the transformation matrices. For the four types of linear transformations and Num(Rᵤ) the number of registration points of the shape u, there are ten cases of indeterminate embedding to consider: a) Num(Rᵤ)=0 under isometric transformations; b) Num(Rᵤ)=1 or 0 under similarity transformations; c) Num(Rᵤ)=2, 1 or 0 under affine transformations; and d) Num(Rᵤ)=3, 2, 1 or 0 under linear transformations.

It is proposed here that the determination of an indeterminate embedding under a linear transformation f can be thought of as a problem of recursively decomposing this transformation as a product of transformations f₁×f₂× . . . fₙ of which one or more need to be specified to make the indeterminate embedding determinate. More specifically, it is proposed here that the shape u should be viewed as an instance of a parameterized shape U comprised by variables x assigned real values determined by a function g to satisfy explicit conditions and constraints. The produced shape g(U) is checked then to see whether there is a transformation f of the shape g(U), such that the shape f(g(U)) is part of the design W. For every match of one of the variables of the shape f(g(U)) in W there is an emergent set of distinguishable registration points that may be selected to determine the visual match.

This multi-stepped process can indeed address all possible cases of indeterminate embedding and it always involves multiple steps to derive the transformation in a sequence. That is, a transformation between two shapes can be represented as the product of a sequence of reflection, translation, and rotation if the transformation is under isometric transformation, a transformation between two shapes can be represented as the product of a sequence of reflection, translation, rotation, and scaling if the transformation is under similar transformation. The transformation between two shapes can be represented as the product of a sequence of reflection, translation, rotation, scaling, shearing, and stretching if the transformation is under affine transformation. The transformation between two shapes can be represented as the product of a sequence of reflection, translation, rotation, scaling, one-point perspectival transformation, and two-point perspectival transformation if the transformation is under projectivity transformation. Even more, the spatial relation between the shape f(g(U)) and the shape W partitions the symmetry group of the shape f(g(U)) into q classes in terms of W, and in congruence with the determinate matchings, it specifies how the shape rule can be used in q distinct ways (Stiny 1991). The section below provides an overview of the ten possible cases of indeterminate embedding that feature less registration points than the ones required for the derivation of the transformation matrices and fills with some detail the sketch outlined above.

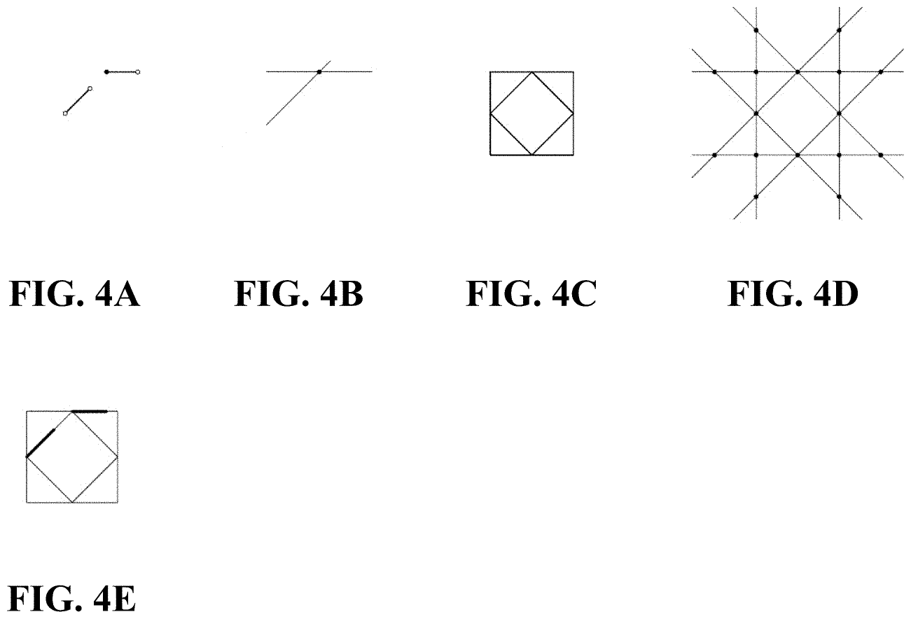

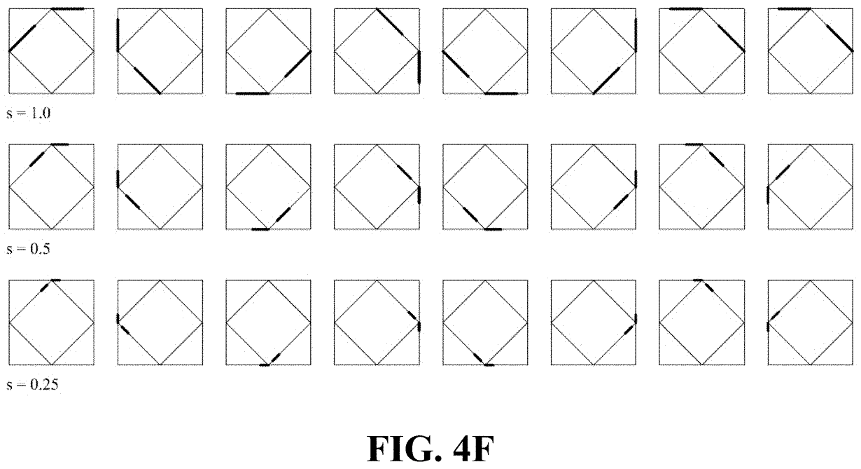

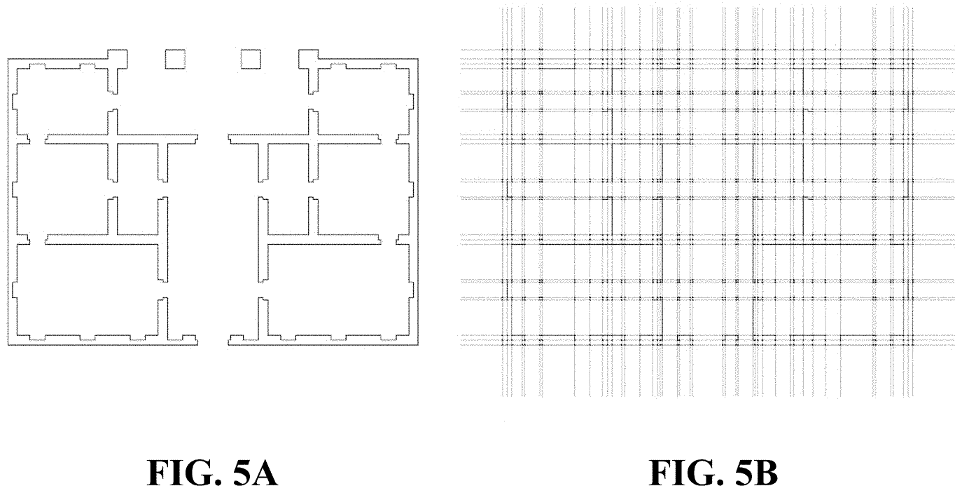

Returning to FIGS. 4A-4F, an overview of the ten possible cases of indeterminate embedding that feature less registration points than the ones required for the derivation of the transformation matrices is presented. FIGS. 4A-4F are an example of an indeterminate embedding under similarity transformations of a shape u having one registration point.

In this example, two registration points are required to resolve the four unknown variables of a similarity matrix including the rotation angle θ, the translation in x direction tₓ, the translation in y direction t_{y} and the scaling factor s. The shape u does not have the required registration points for the derivation of the similarity matrix and the computation fails. To address this problem, a two-stepped process is used to determine the embedding results.

The first step is processed automatically by taking one registration point of g(U) to derive tₓ and t_{y} which are the variables of translation. The second step is processed automatically by taking one registration point and one endpoint of g(U) to derive the angle 9 which is the variable of rotation. The third step requires an additional input for the scaling factor s because the indeterminacy occurs in scaling. The process of dealing with indeterminate embedding in scaling is similar to the indeterminate embedding in translation and it can be similarly resolved by manual visual inspection or an automated optimization calculation. The shape embedding can be parameterized with a scaling parameter s that has a scaling range lower bound s upper bound, in this example, the lower bound=0 and upper bound=1. The calculation of lower bound and upper bound is context-sensitive, and the indeterminacy might show up as multiple parameters. In this example, there is a single embedding schema of the shape f(g(U)) in the shape W, eight matches under the symmetry group of the shape W, and for each one of them there is an assignment g parameterized with a scaling factors with a range 0≤s≤1.

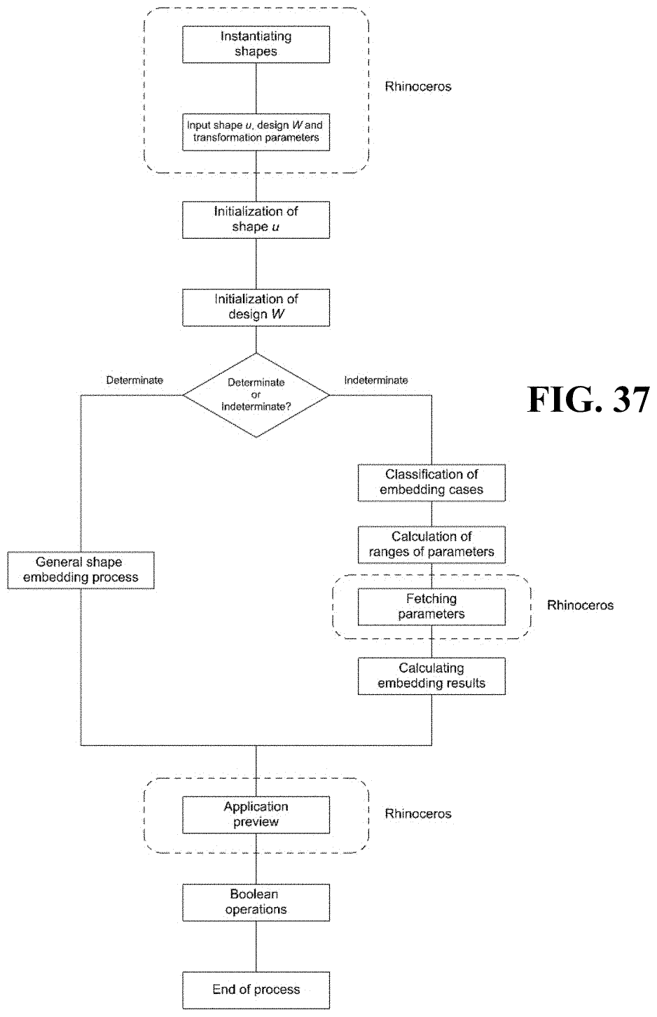

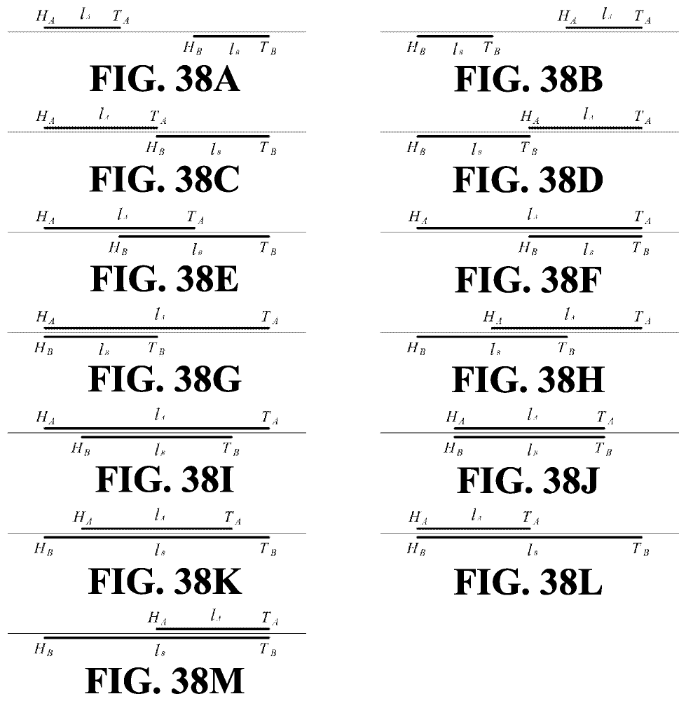

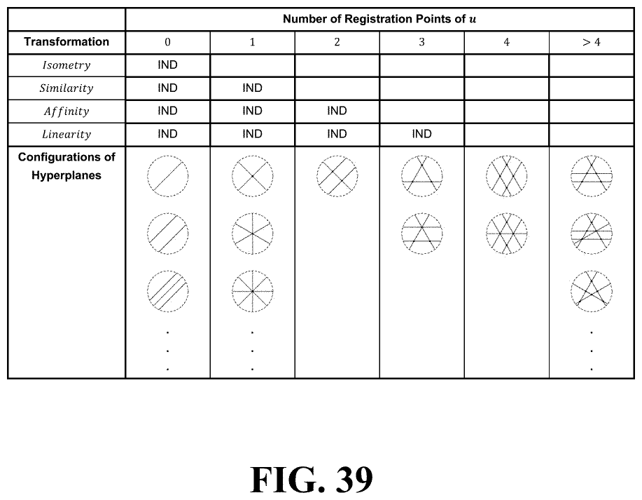

For each case of indeterminate embedding, system pre-calculates respective parameter ranges and echoes a message back to users to ask for further information so that the embedding can be determinate. The complete ten cases of indeterminate embedding and their parameter ranges are listed in the work by Hong and Economou (Hong and Economou, 2021). To achieve this mechanism, system requires three components: 1) a component to detect indeterminacy of embedding and classify the case, 2) a component to calculate the range for each parameter and 3) an interactive interface that can communicate with users without disrupting the workflow. FIG. 37 shows the flowchart when the present invention is dealing with indeterminacy.

Weighting, Ranking and Sampling Registration Points

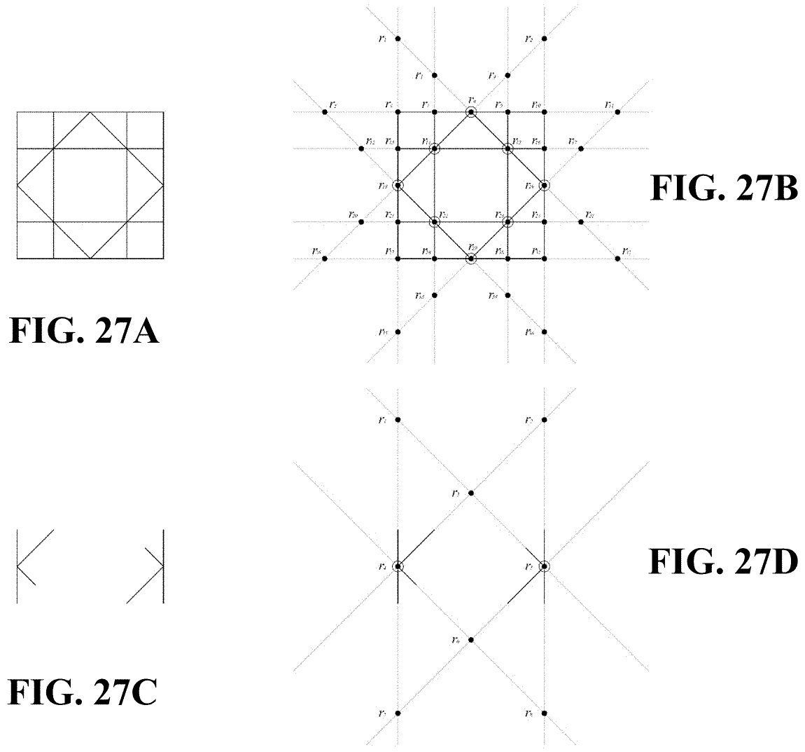

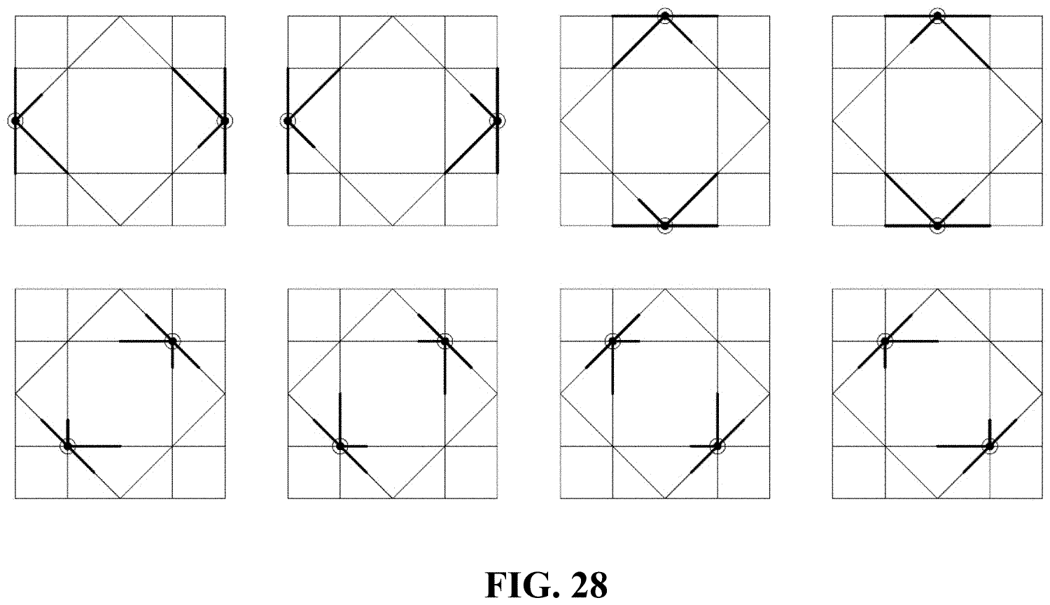

To resolve the issue of low performance of shape embedding, a mechanism is proposed to reduce the search body while processing shape embedding. By revisiting each registration point of shape u, it is observed that not every registration point of u can be embedded in any registration point of W after applying a transformation. FIGS. 27A-27D are an example of registration point embedding. FIG. 27A: a design W comprising 12 maximal lines embedded in 12 hyperplanes; FIG. 27B: among 36 registration points at which 12 hyperplanes intersect, eight of them (highlighted by circles) are able to contain the two registration points (highlighted by circles in (FIG. 27D)) of u; FIG. 27C: a shape u comprising six maximal lines embedded in six hyperplanes; FIG. 27D: eight registration points at which six hyperplanes intersect, among these registration points, two of them (highlighted by circles) can be only embedded in the eight of the registration points (highlighted by circles in (FIG. 27B)) of W. Thus, only eight out of 36 registration points of W are able to “contain” the two registration points of u. By extending this concept, each registration point can be weighted with the maximal lines that are intersecting at the registration point.

Sampling the registration points of u with a pre-process of weighting and ranking these registration points which can be embedded in the least registration points of W will greatly reduce the search space. In the example of FIGS. 27A-27D, the search space is reduced from C₂³⁶=630 to C₂⁸=28. If the embedding is processed under affine transformation, the search space can be reduced from C₃³⁶r=7140 to C₁⁶=6 (two registration points can be determined, the system selects one from the rest of six); the search space can be reduced from C₄³⁶=58905 to C₂⁶=15 (two registration points can be determined, the system selects two from the rest of six). FIG. 28 illustrations the eight results of embedding under similar transformation of the previous example. The two sampled registration points of u can only be embedded in the eight selected registration points of W. Shape embedding of the example of FIGS. 27A-27D and the two sampled registration points of u can be embedded in the eight selected registration points of W.

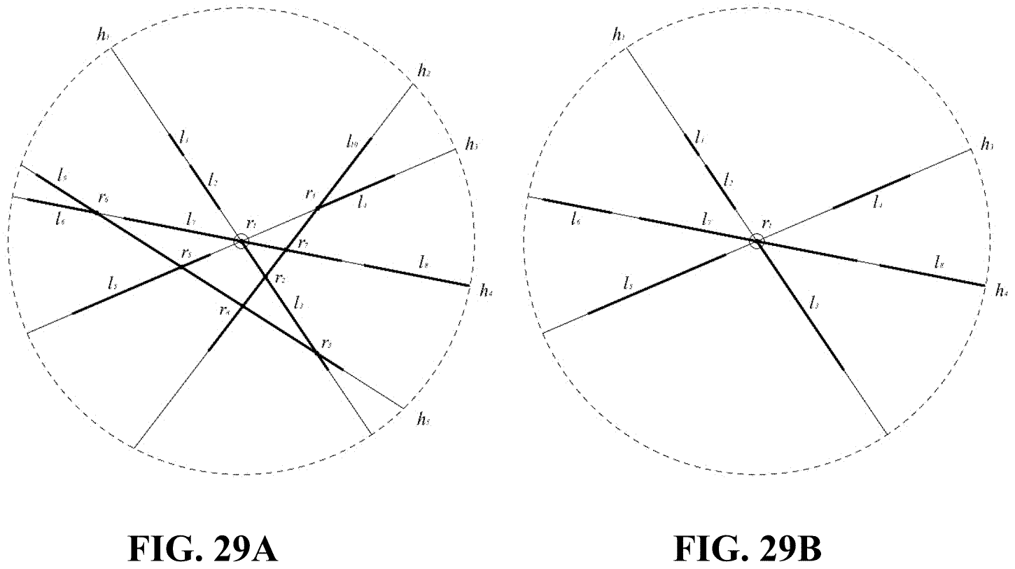

From the example of FIG. 28, it is clear that weighting and ranking registration points before sampling them can greatly help improve the performance of shape grammar interpreter. A detailed description of weighting and ranking of registration points is hereinafter introduced. Each registration point appears to be an intersection point of two or more than two hyperplanes where equal or more number of maximal lines are embedded. FIGS. 29A-29B are an example of weighting process of a registration point when all lines share identical attributes. FIG. 29A: A shape comprising ten maximal lines embedded in four hyperplanes and FIG. 29B: one of the registration points intersected by eight maximal lines embedded in three hyperplanes.

FIGS. 29A-29B shows a shape comprising ten maximal lines embedded in four hyperplanes that intersect at eight registration points. Taking one of the registration points r₁ as an example, eight maximal lines embedded in three hyperplanes intersect at this registration point.

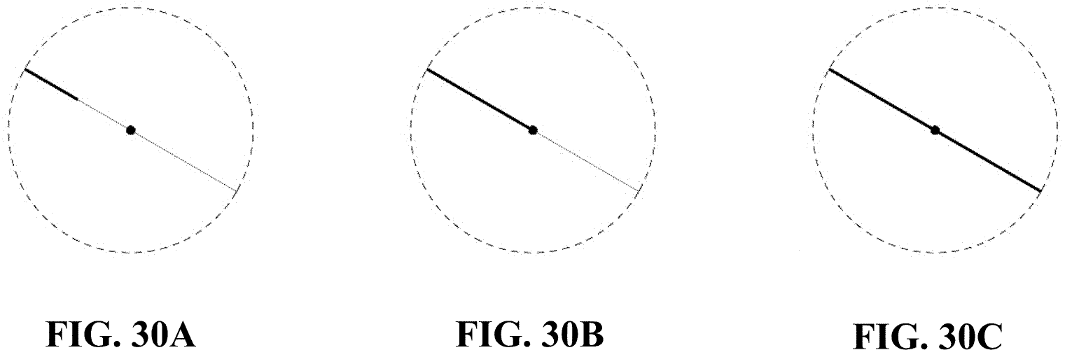

A simple method to weight this registration point is by counting the number of hyperplanes that intersect at this registration point. However, number of hyperplanes may not be enough to provide an improvement to make performance practical. To obtain more improvement, more information of maximal lines should be introduced. There three configurations of a maximal line and a registration point shown in FIGS. 30A-30C. FIG. 30A: the first configuration c₁ that the registration point is not occurring on the maximal line; FIG. 30B: the second configuration c₂ that the registration point is occurring on the endpoint of the maximal line; FIG. 30C: the third configuration c₃ that the registration point is occurring on the body of the maximal line.

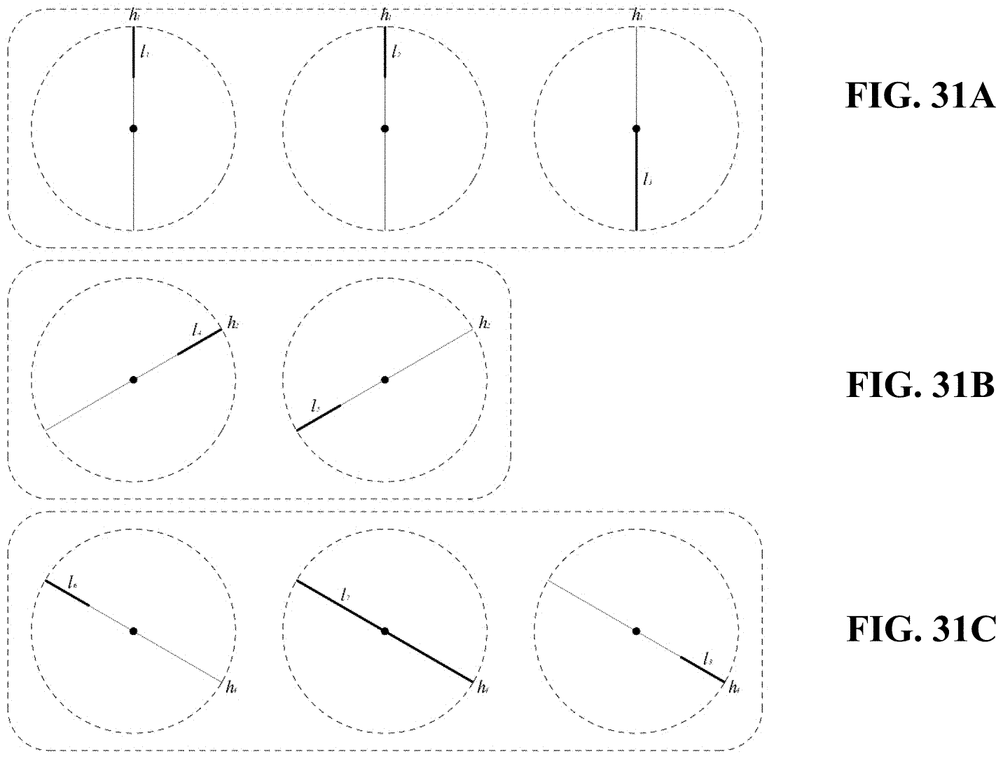

Thus, these three configurations named cₛ, c₂ and c₃ are in part relations c₁<c₂<c₃. That is, any registration point of W where a maximal line with the configuration c₃ is possible to be embedded in, must be a possible registration point for a maximal line with configurations c₂ or c₁ to be embedded in. In other words, if a registration point of u with the configuration c₃ is possible to be embedded in a registration point of W, there must be a possibility to embed a registration point that has configuration c₂ or c₁ in the registration point of W. Hence, the configuration of each maximal line intersecting at the registration point in FIG. 29B can be normalized and shown in FIGS. 31A-31C. FIG. 31A: three normalized maximal lines embedded in the hyperplane h₁; FIG. 31B: two normalized maximal lines embedded in the hyperplane h₂;

FIG. 31C: three normalized maximal lines embedded in the hyperplane h₄.

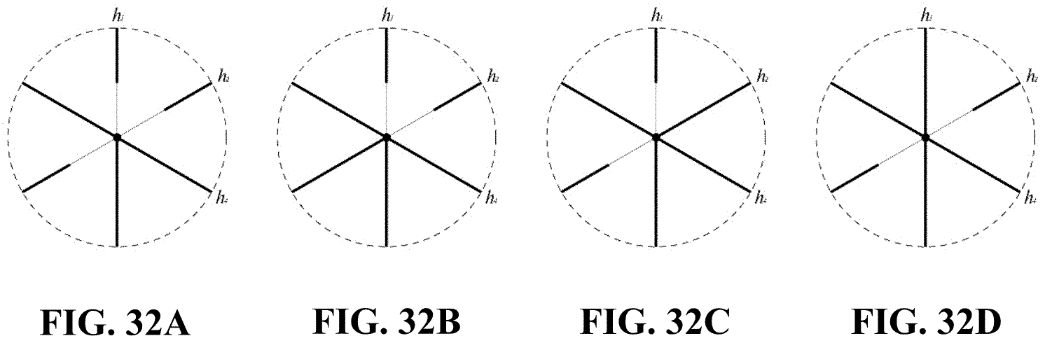

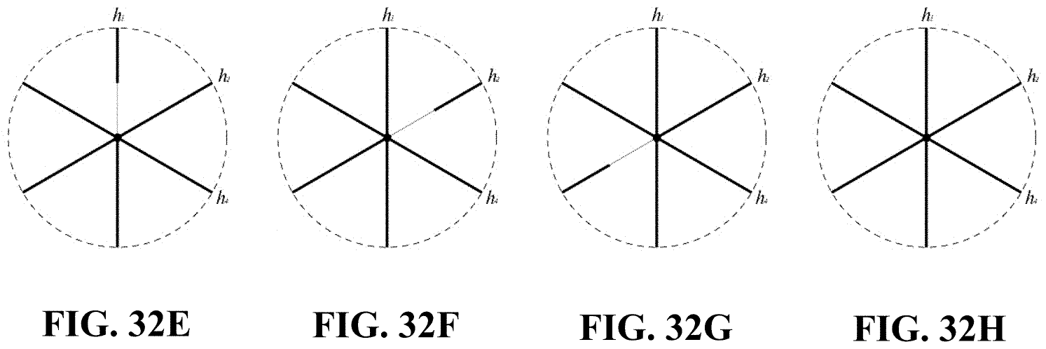

To obtain a simplest form of the weight of a registration point, these normalized maximal lines can be merged according to the part relations among them. For instance, the normalized l₁ and normalized l₂ can be merged as l_{1,2} because they have equivalent chance to be embedded in. Also, l₆ and l₈ can be merged into l₇ as l_{6,7,8} because both l₆ and l₇ are parts of l₇. After reduction, the simplest form of the normalized maximal lines intersecting at this registration point and all its supersets are shown in FIGS. 32A-32H. FIG. 32A: The simplest form of the normalized maximal lines intersecting at the registration point; FIGS. 32B-32H: seven supersets of the normalized weight of the registration point.

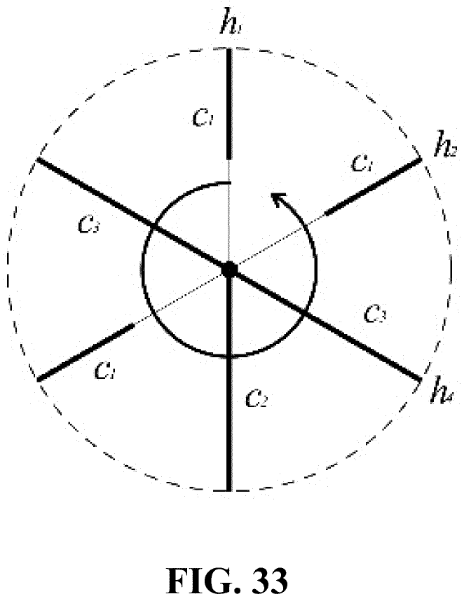

To obtain the data representation of the weight, a simple convention can be followed to describe the weight of a registration point. Imagine that we stand on a registration point and look outward in a direction along with any hyperplane and record the configurations of the maximal lines one by one in the counter-clock-wise rotation. The simplest form of weight of the registration point in the example above can be described as: c₁-c₃-c₁-c₂-c₃-c₁, and a visual explanation is shown in FIG. 33.

Note that the two c₃ are the same normalized maximal line embedded in the hyperplane h₄. Also, the first c₁ and the c₂ are representing the maximal lines embedded in the same hyperplane h₁. To describe the weight more precisely, it can be rewritten in a folded form as:

$$[ \begin{matrix}{c}_{1} \\ {c}_{2}\end{matrix} ] - [ \begin{matrix}{c}_{3} \\ {c}_{3}\end{matrix} ] - [ \begin{matrix}{c}_{1} \\ {c}_{1}\end{matrix} ] .$$

All the alternative forms of the weight of this registration point are:

$$[ \begin{matrix}{c}_{3} \\ {c}_{3}\end{matrix} ] - [ \begin{matrix}{c}_{1} \\ {c}_{1}\end{matrix} ] - [ \begin{matrix}{c}_{2} \\ {c}_{1}\end{matrix} ] , [ \begin{matrix}{c}_{1} \\ {c}_{1}\end{matrix} ] - [ \begin{matrix}{c}_{2} \\ {c}_{1}\end{matrix} ] - [ \begin{matrix}{c}_{3} \\ {c}_{3}\end{matrix} ] , \\ [ \begin{matrix}{c}_{2} \\ {c}_{1}\end{matrix} ] - [ \begin{matrix}{c}_{3} \\ {c}_{3}\end{matrix} ] - [ \begin{matrix}{c}_{1} \\ {c}_{1}\end{matrix} ] , [ \begin{matrix}{c}_{3} \\ {c}_{3}\end{matrix} ] - [ \begin{matrix}{c}_{1} \\ {c}_{1}\end{matrix} ] - [ \begin{matrix}{c}_{1} \\ {c}_{2}\end{matrix} ] and [ \begin{matrix}{c}_{1} \\ {c}_{1}\end{matrix} ] - [ \begin{matrix}{c}_{1} \\ {c}_{2}\end{matrix} ] - [ \begin{matrix}{c}_{3} \\ {c}_{3}\end{matrix} ]$$

depending on which hyperplane we start. The supersets of the weight shown in FIGS. 32A-32H can be described in the same manner:

$$\begin{matrix}[ \begin{matrix}{c}_{1} \\ {c}_{2}\end{matrix} ] - [ \begin{matrix}{c}_{3} \\ {c}_{3}\end{matrix} ] - [ \begin{matrix}{c}_{1} \\ {c}_{1}\end{matrix} ] ; & FIG . 32 A \\ [ \begin{matrix}{c}_{1} \\ {c}_{2}\end{matrix} ] - [ \begin{matrix}{c}_{3} \\ {c}_{3}\end{matrix} ] - [ \begin{matrix}{c}_{2} \\ {c}_{1}\end{matrix} ] ; & FIG . 32 B \\ [ \begin{matrix}{c}_{1} \\ {c}_{2}\end{matrix} ] - [ \begin{matrix}{c}_{3} \\ {c}_{3}\end{matrix} ] - [ \begin{matrix}{c}_{1} \\ {c}_{2}\end{matrix} ] ; & FIG . 32 C \\ [ \begin{matrix}{c}_{3} \\ {c}_{3}\end{matrix} ] - [ \begin{matrix}{c}_{3} \\ {c}_{3}\end{matrix} ] - [ \begin{matrix}{c}_{1} \\ {c}_{1}\end{matrix} ] ; & FIG . 32 D \\ [ \begin{matrix}{c}_{1} \\ {c}_{2}\end{matrix} ] - [ \begin{matrix}{c}_{3} \\ {c}_{3}\end{matrix} ] - [ \begin{matrix}{c}_{3} \\ {c}_{3}\end{matrix} ] ; & FIG . 32 E \\ [ \begin{matrix}{c}_{3} \\ {c}_{3}\end{matrix} ] - [ \begin{matrix}{c}_{3} \\ {c}_{3}\end{matrix} ] - [ \begin{matrix}{c}_{2} \\ {c}_{1}\end{matrix} ] ; & FIG . 32 F \\ [ \begin{matrix}{c}_{3} \\ {c}_{3}\end{matrix} ] - [ \begin{matrix}{c}_{3} \\ {c}_{3}\end{matrix} ] - [ \begin{matrix}{c}_{1} \\ {c}_{2}\end{matrix} ] ; & FIG . 32 G \\ [ \begin{matrix}{c}_{3} \\ {c}_{3}\end{matrix} ] - [ \begin{matrix}{c}_{3} \\ {c}_{3}\end{matrix} ] - [ \begin{matrix}{c}_{3} \\ {c}_{3}\end{matrix} ] . & ( h )\end{matrix}$$

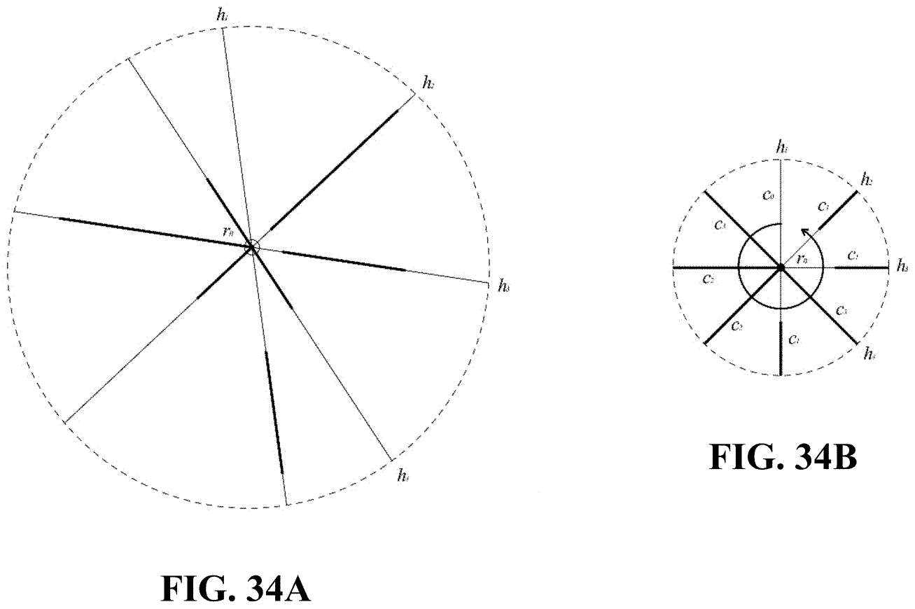

Note that a registration point of W in which a registration point of u can be embedded may have more hyperplanes. For instance, the following representation is the weight of a registration point r_{B} at which four hyperplanes intersect (see FIGS. 34A-34B):

$$[ \begin{matrix}{c}_{0} \\ {c}_{1}\end{matrix} ] - [ \begin{matrix}{c}_{3} \\ {c}_{3}\end{matrix} ] - [ \begin{matrix}{c}_{2} \\ {c}_{1}\end{matrix} ] - [ \begin{matrix}{c}_{2} \\ {c}_{1}\end{matrix} ] .$$

FIGS. 34A-34B are an example of a registration point r_{B} at which four hyperplanes intersect and the weight is a superset of the weight of the registration point in FIGS. 32A-32B. FIG. 34A: a registration point at which six maximal lines embedded in four hyperplanes intersect; FIG. 34B: the normalized form of registration point r_{B}.

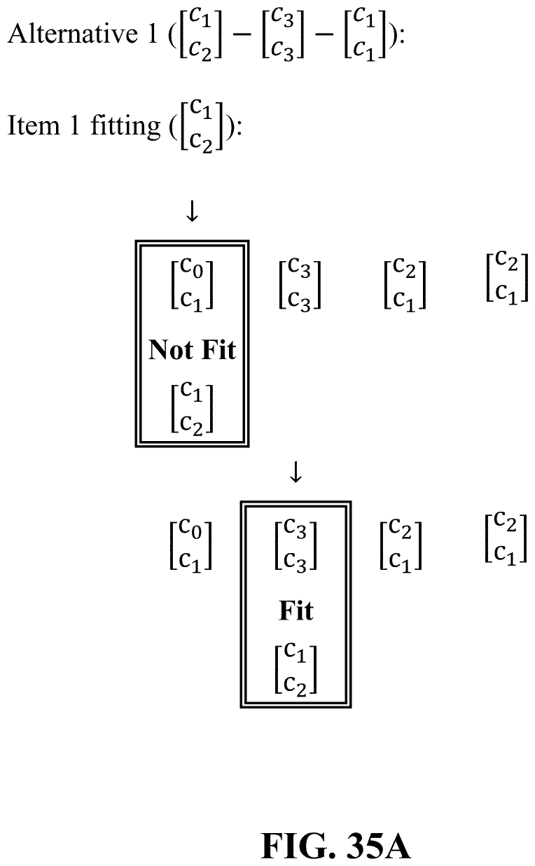

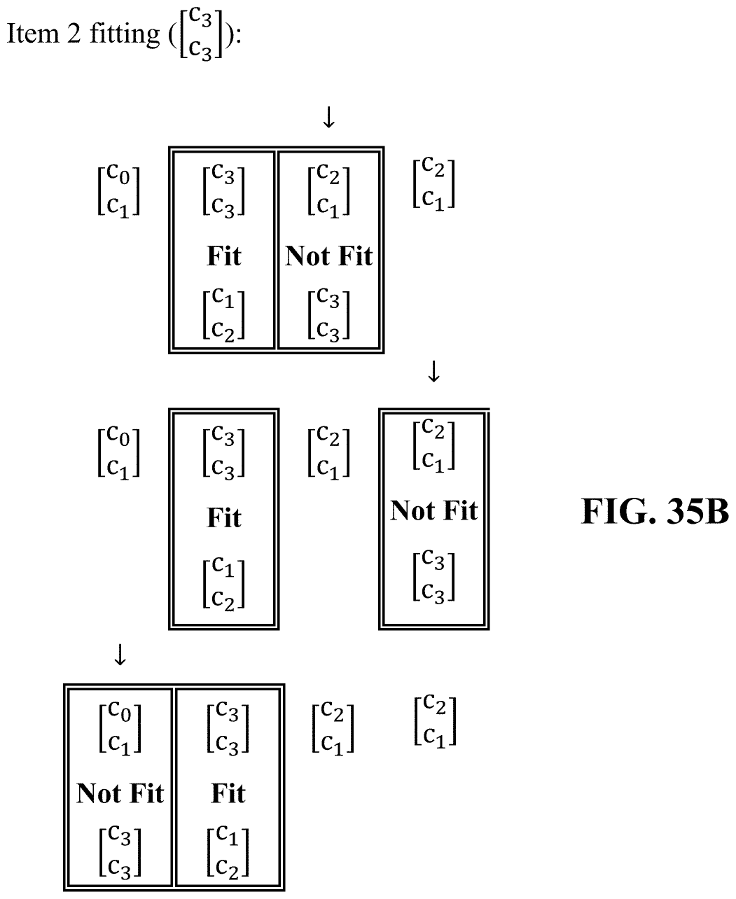

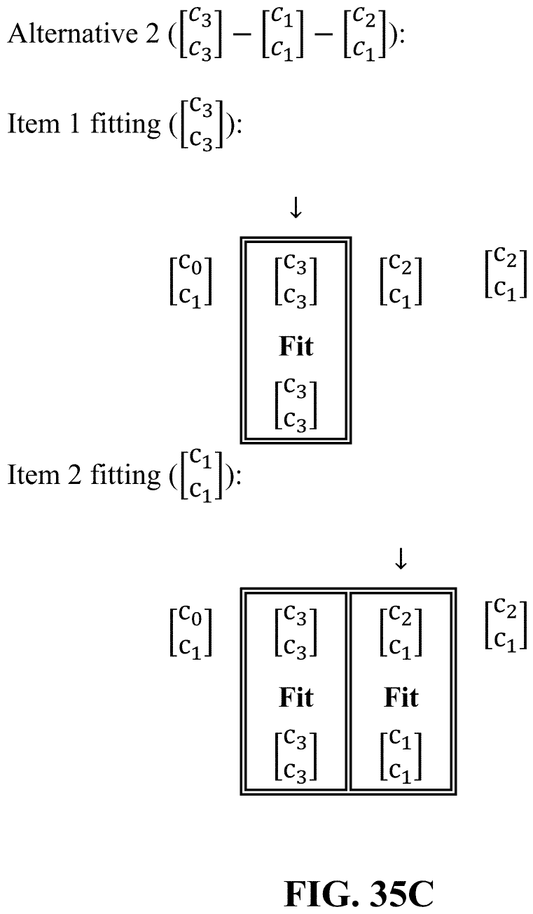

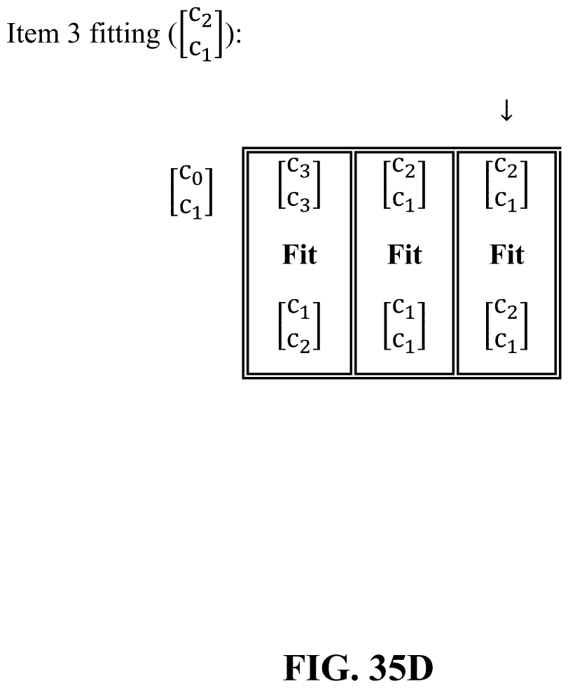

The system checks if it is possible to embed r_{A} into r_{B} by checking the weights in a cyclic manner. See, FIGS. 35A-35D. For example, the system checks if the first item of the w_{A}

$$( [ \begin{matrix}{c}_{1} \\ {c}_{2}\end{matrix} ] )$$

is a subset of the item of the w_{B} with the smallest index. In this example, the second item is the superset with smallest index because the first item is not a superset of

$$[ \begin{matrix}{c}_{1} \\ {c}_{2}\end{matrix} ] .$$

After fitting the first item into w_{B}, the system starts to fit the second item into w_{B}. Note that the second item can only be fit into the items after the second one of w_{B} because of the order. In this example, there is no item of w_{B} after the second item that is a superset of the second item of w_{A}, therefore, this alternative of w_{A} is failed to be fit into w_{B}, then, the system will process the next alternative until all the items of w_{A} can be fit into w_{B}.

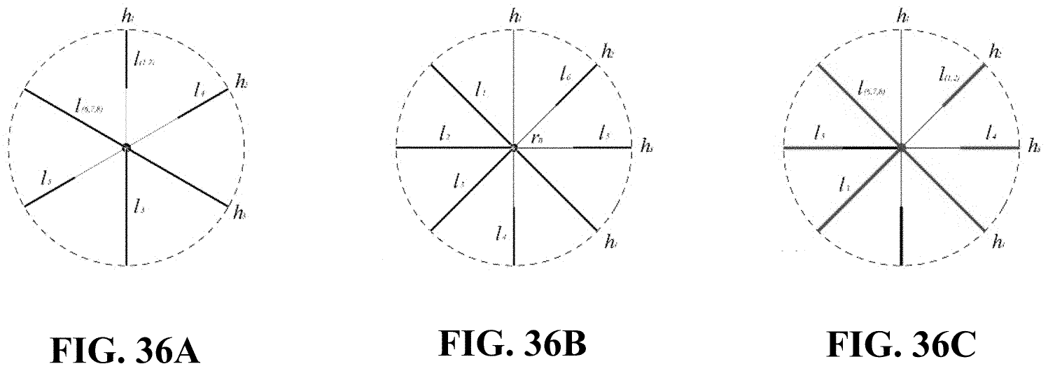

For Alternative 1, the item 2 cannot be fit into w_{B}, so this alternative cannot be embedded in and the system will test the nest alternative. For Alternative 1, all the three items of w_{A} can fit into w_{B} in an order, so this registration points r_{B} will be labeled as a candidate. A visualization of the registration point embedding is shown in FIGS. 36A-36C. FIG. 36A: a normalized registration point at which five normalized maximal lines embedded in three hyperplanes intersect;

FIG. 36B: a normalized registration point at which six normalized maximal lines embedded in four hyperplanes intersect; FIG. 36C: the result of embedding. Note that the length of the lines and the angles between hyperplanes do not matter because they are diagrams to explain how the system generates the weight for each registration point so that the geometric features are discarded.

There are future considerations to extend the present shape machine 200 for more shape types in 3D space. For example, the precision errors never go away even with the innovative calibration system. This issue might become more severe when the complexity of the computation increases, for example, the complex curves and the shape types in 3D space will cause higher complexity on calculation, and the precision errors will be accumulated and fail the system.

The performance of shape embedding needs advancing while dealing with complex shapes or the shapes in 3D space, especially when the shape embedding is processed under linear transformation, because the computation complexity will increase exponentially.

Further, there will be more indeterminate cases and the relationships among these transformation parameters will be very perplex.

Fortunately, the accuracy of CAD systems and the computation power of computers are improved year over year, especially as parallel computation becomes a critical part of the present technology.

### REFERENCES

The following references are used herein and incorporated by reference in their entirety.
[1] Alberti L B (1966), On Painting, Trsl. J R Spencer, Yale University Press.
[2] Besl P J, Jain R C (1985) Three-dimensional object recognition. ACM Comput. Surv. 17, 1, 75-145.
[3] Campbell R J, Flynn P J (2001) A survey of free-form object representation and recognition techniques. Computer Vision and Image Understanding 81(2):166-21.
[4] Cardone A, Gupta S K, Karnik M (2003) A survey of shape similarity assessment algorithms for product design and manufacturing applications. Journal of Computing and Information Science in Engineering 3:109-118.
[5] Chase S C (1989) Shapes and shape grammars: from mathematical model to computer implementation. Environment and Planning B: Planning and Design 16, 215-242.
[6] Chase S C (2010) Shape grammar implementations: the last 35 years. Proceedings of the 4th International Conference Design Computing and Cognition, Stuttgart. Accessed Apr. 20, 2020. https://www.researchgate.net/publication/230441758_Spatial_grammar_implementation_From_theory_to_useable_software.
[7] Chau H H (2004) Evaluation of a 3d shape grammar implementation. In Gero J S (ed.). Design Computing and Cognition'04. Dordrecht, The Netherlands, Kluwer Academic Publishers, 357-376.
[8] Cormen T H, Leiserson C E, Rivest R and Stein C (2009) Introduction to algorithms, 3rd ed. Cambridge, Mass.: MIT PressCorreia RC (2013).
[9] Correia R C (2013) DESIGNA—A shape grammar interpreter. MSc thesis, Instituto Superior Te'cnico, Universidade de Lisboa, Lisbon, Portugal.
[10] Earl C (1997) Shape boundaries. Environment and Planning B: Planning and Design 24: 669-687.
[11] Eloy S, Pauwels P, Economou A (2018) A. Promises of shape grammars in advances in implemented shape grammars: solutions and applications. AI EDAM Special Issue: Artificial Intelligence for Engineering Design, Analysis and Manufacturing, 32(2), Cambridge University Press, 131-137.
[12] Foley J, Van Dam A, Feiner S, and Hughes J. (1997) Computer Graphics: Principles and Practice, Addison-Wesley.
[13] Gips J (1999) Computer implementation of shape grammars. Proceedings of the Workshop on Shape Computation, MIT. Accessed Apr. 20, 2020. https://www.academia.edu/.3089939/Computer_Implementation_of_Shape_Grammars.
[14] Grasl T (2012) Transformational Palladians, Environment and Planning B: Planning and Design, 39, 1, 83-95.
[15] Grasl T, Economou A (2013) From topologies to shapes: Parametric shape grammars implemented by graphs. Environment and Planning B: Planning and Design 40(5), 905-922.
[16] Grasl T, Economou A (2018) From Shapes to Topologies and Back: An introduction to a General Parametric Shape Grammar Interpreter. Advances in Implemented Shape Grammars: Solutions and Applications. AI EDAM, 32(2) Cambridge University Press, 208-224.
[17] Hong T K, Economou A (forthcoming) What Shape Grammars Do that CAD Should: The 14 Cases of Shape Embedding.
[18] Hong T K, Economou A (2020) Five criteria for shape grammar interpreters. Design Computing and Cognition. (DCC) eds: J. S. Gero, Springer, 189-208.
[19] Jowers I, Earl C (2011) Implementation of curved shape grammars. Environment and Planning B: Planning and Design 38(4), 616-635.
[20] Knight T (1994) Transformations in design: A formal approach to stylistic change and innovation in the visual arts, Cambridge University Press.
[21] Krishnamurti R (1981) The construction of shapes, Environment and Planning B: Planning and Design, 8, 5-40.
[22] Krishnamurti R (1982) SGI: a shape grammar interpreter. Centre for Configurational Studies, Milton Keys, UK: The Open University.
[23] Krishnamurti R, Giraud C (1986) Towards a shape editor: the implementation of a shape generation system. Environment and Planning B: Planning and Design 13(4), 391-404.
[24] Krishnamurti R (1992) The arithmetic of maximal planes. Environment and Planning B: Planning and Design 19, 431-464.
[25] Krishnamurti R (2015) Mulling over shapes, rules and numbers. Nexus Network Journal, 17(3), 930-945.
[29] Loncaric S (1998) A survey of shape analysis techniques. Pattern Recogn 31(8):983-1001.
[30] McKay A, Chase S, Shea K, Chau H H (2012) Spatial grammar implementa-tion: from theory to usable software. Artificial Intelligence for Engineering Design, Analysis and Manufacturing, 29, 143-159.
[31] Ruiz-Montiel M, Belmonte M V, Boned J, Mandow L, Millán E, Badillo A R, Pérez J L (2014) Layered shape grammars. Computer-Aided Design, 56, 114-119.
[29] Schoot J, Troost K, Migura S, Kneer B (2016) Improving the resolution of extreme-UV lithography scanners. SPIE Newsroom.
[30] Stiny G (1975) Pictorial and formal aspects of shape and shape grammars. In-terdisciplinary Systems Research, Birkhauser.
[31] Stiny G (1980) Introduction to shape and shape grammars, Environment and Planning B, Planning and Design 7, 343-351.
[32] Stiny G (1989) Formal devices in design. In: Design Theory 8, eds. SA Newsome, W R Spillers, S Finger, New York: Springer-Verlag; p. 173-188.
[33] Stiny G (1991) The algebras of design. Research in Engineering Design Springer-Verlag New York Inc; 2: p. 171-181.
[34] Stiny G (2006) Shape: talking about seeing and doing, MIT Press.
[35] Stouffs R (2018) Where associative and rule-based approaches meet. T. Fukuda, W. Huang, P. Janssen, K. Crolla, S. Alhadidi (eds), Proceedings of CAADRIA 2018, V2, 453-462.
[36] Stouffs R, Li A (2020) Learning from users and their interaction with a dualinterface shape-grammar implementation, Proceedings of CAADRIA.
[37] Tapia M (1999) A visual implementation of a shape grammar system. Environment and Planning B: Planning and Design 29, 59-73.
[38] Tapia (1996) From shape to style. Shape grammars: issues in representation and computation. PhD thesis, Department of Computer Science, University of Toronto, Toronto, Canada.
[39] Tangelder H, Veltkamp R C (2008). A Survey of Content Based 3D Shape Retrieval Methods, Multimedia Tools Applications 39:441-471.
[40] Veltkamp R C, Hagedoorn M. (2001). State of the Art in Shape Matching. In Principles of visual information retrieval. Springer, pp. 87-119.

It will be clear to a person skilled in the art that features described in relation to any of the embodiments described above can be applicable interchangeably between the different embodiments. The embodiments described above are examples to illustrate various features of the invention.

The reader's attention is directed to all papers and documents which are filed concurrently with or previous to this specification in connection with this application and which are open to public inspection with this specification, and the contents of all such papers and documents are incorporated herein by reference.

Numerous characteristics and advantages have been set forth in the foregoing description, together with details of structure and function. While the invention has been disclosed in several forms, it will be apparent to those skilled in the art that many modifications, additions, and deletions, especially in matters of shape, size, and arrangement of parts, can be made therein without departing from the spirit and scope of the invention and its equivalents as set forth in the following claims. Therefore, other modifications or embodiments as may be suggested by the teachings herein are particularly reserved as they fall within the breadth and scope of the claims here appended.

We claim:

1. A system for shape embedding and shape replacement in generative modelling comprising:
a system architecture to account for modules and processes required for automated embedding and replacement of shapes made up of lines;
a calibration mechanism to address precision errors;
a pictorial algorithm of shape embedding under perspectival transformations to deal with linear transformations;
a two-step mechanism to deal with indeterminate embedding;
a ranking system of registration points to improve shape embedding performance; and
a layered system structure to achieve integration of rule definitions and applications in shape computation.

2. The system of claim 1, wherein the system is configured to separate visual rules from their symbolic counterparts.

3. The system of claim 1, wherein the system is configured to compile shape rules drawn by users into an executable form and execute them to carry forward a shape computation.

4. A shape grammar interpreter configured to compile shape rules drawn by users into an executable form and execute them to carry forward a shape computation comprising:
a system architecture to account for modules and processes required for automated embedding and replacement of shapes made up of lines;
a calibration module to address precision errors;
a transformation module with a pictorial algorithm of shape embedding under perspectival transformations to deal with linear transformations;
an indeterminate embedding module;
a ranking module of registration points to improve shape embedding performance; and
a layered system structure to achieve integration of rule definitions and applications in shape computation.

5. A shape system comprising:
one or more processors; and
a memory in communication with the one or more processors, storing instructions, that when executed, cause the system to:
implement a set of reduction rules to uniquely describe drawn shapes in terms of a smallest number of maximal elements that specify the shape;
implement shape recognition for the drawn shapes comprising one or more of straight lines, arcs and their combinations under all Euclidean transformations; and
implement a rule compiler of shape modification for the drawn shapes comprising one or more of straight lines, arcs and their combinations under all Euclidean transformations.
